(19) United States
(12) Patent Application Publication
(10) Pub. No.: US 2021/0248279 A1
(43) Pub. Date: Aug. 12, 2021

(54) PROCESS FOR CONSTRUCTING A THREE DIMENSIONAL MODEL OF THE LIVING SPACE OR INTERIOR SPACE OF A HOUSE OR BUILDING FROM A FLOOR-PLAN DRAWING OF THE HOUSE OR BUILDING FOR USE IN SIZING HVAC SYSTEMS, SIZING AIR DUCTING SYSTEMS, OR OTHER ENERGY MODELING FOR THE HOUSE OR BUILDING

(71) Applicant: William Russell King, Thornton, CA (US)

(72) Inventor: William Russell King, Thornton, CA (US)

(21) Appl. No.: 16/783,529

(22) Filed: Feb. 6, 2020

(51) Int. Cl. G06F 30/13; G06T 17/10; G06T 17/20; G06T 15/10

(52) U.S. Cl. CPC G06F 30/13; G06T 15/10; G06T 17/20; G06T 17/10

(57) ABSTRACT

The process for constructing a three dimensional model of the living space or interior space of a house or building from a floor-plan drawing of the house or building using special imaginary “building blocks” that are scalable cuboids and/or scalable triangular prisms to completely fill in the living space or interior space detailed on a two-dimensional floor plan of the house or building to create the overall three-dimensional model of the living space or interior space. This invention is paired with other software programs, wherein this invention is first used to determine the surface area and description/type of each segment of the total exterior surface of the conditioned shell, living space, or interior space of the house or building, which is then entered into other software programs in order to determine the optimum size of HVAC system and/or the optimum size and structure of air ductwork or ducting and/or other energy modeling calculations.

### BACKGROUND OF THE INVENTION

### 1. Field of the Invention

This invention relates to methods, processes, and calculations used in energy modeling software, which is used to determine the optimum size of heating ventilation and air conditioning (HVAC) system and ducting system for a house or building along with other criteria related to energy usage by the house or building. This invention is computer software that builds a three-dimensional model of the living space or interior space of a house or building from a standard floor plan drawing of the house or building. The software then determines the surface area and composition of each segment of the overall exterior surface of the three-dimensional model, including specific information for each wall, wall segment, ceiling, ceiling segment, floor, floor segment, window, and door on the exterior surface of the living space or interior space. This data is then plugged into or entered into separate formulas or other software programs that are used to determine the optimum size of HVAC system and/or the optimum size and structure of air ductwork or ducting and/or other energy modeling calculations.

### 2. Description of Related Art

There are several software programs in the prior art that determine the optimum size of HVAC system for a house or building. There are several software programs in the prior art that determine the optimum size and structure of air ductwork or ducting for a house or building. There are several software programs in the prior art that perform energy modeling for a house or building. All of these software programs require the input of the surface area and description of each segment of the total exterior surface, or other geometrical properties, of the conditioned shell, boundary of living space, living space, or interior space of the house or building in order to determine the optimum size of HVAC system and/or the optimum size and structure of air ductwork or ducting and/or other energy modeling. All of these software programs also require the input of location, environment, and weather conditions of the location of the house or building. This information is typically entered by hand or by keyboard into the prior art software. These software programs may be designated as HVAC Design software or Energy Modeling software. The current way to determine the required input data for HVAC Design software, Ductwork Design software, and Energy Modeling software is to calculate these data by hand. Typically, an Engineer calculates the area of each wall, floor, and ceiling of the exterior surface of the living space or interior space and the Engineer then enters these details, including surface area and composition of each wall, wall segment, ceiling, ceiling segment, floor, floor segment, window, and door on the exterior surface of the living space or interior space into the HVAC Design software, Ductwork Design software, or Energy Modeling software.

This invention is a very simple and easy-to-use method or process to determine the input parameters of HVAC Design software, Ductwork Design software, or Energy Modeling software by building a three-dimensional model of the living space or interior space of a house or building from a standard floor plan drawing. This invention uses special imaginary “building blocks” that are scalable cuboids and/or scalable triangular prisms to completely fill in the living space or interior space to create the overall three-dimensional model of the living space or interior space. No other software builds a three-dimensional model of the living space or interior space using scalable cuboids and/or scalable triangular prisms. This invention is paired with other software programs, wherein this invention is first used to determine the surface area and description/type of each segment of the total exterior surface of the conditioned shell, boundary of living space, living space, or interior space of the house or building, which is then plugged into or entered into other software programs to determine the optimum size of HVAC system and/or the optimum size and structure of air ductwork or ducting and/or other energy modeling calculations. The exterior surface information may be entered into the other software programs by hand with a keyboard or may be entered automatically wherein this invention is a subroutine or component of the other software programs or vice versa. The applicant has license agreements to run many other software packages within the software of this invention. This invention is the first piece of software that can build a detailed three-dimensional model of the living space or interior space of a house or building from a standard floor plan drawing using scalable cuboids and scalable triangular prisms to build or fill in each room on the floor plan as described below to yield an overall three-dimension model of the exterior surface of the conditioned shell or boundary of interior space of the house or building. Importantly, this invention keeps a real time tabulation of the surface area and composition of each wall, wall segment, ceiling, ceiling segment, floor, floor segment, window, and door of the three-dimensional model as each scalable cuboid or scalable triangular prism is added to build the three-dimensional model. This tabulation of the surface area and composition of each wall, wall segment, ceiling, ceiling segment, floor, floor segment, window, and door is the data that is entered into the other software programs in order to determine the optimum size of HVAC system and/or the optimum size and structure of air ductwork or ducting and/or other energy modeling calculations.

### BRIEF SUMMARY OF THE INVENTION

It is an aspect of the process for constructing a three dimensional model of the living space or interior space of a house or building from a floor-plan drawing of the house or building for use in sizing HVAC systems, sizing air ducting systems, or other energy modeling for the house or building to include the process for constructing a three dimensional model of the living space or interior space of a house or building from a floor-plan drawing of the house or building for use in sizing HVAC systems, sizing air ducting systems, or other energy modeling for the house or building using imaginary “building blocks” that are scalable cuboids and/or scalable triangular prisms to completely fill in the living space or interior space to create the overall three-dimensional model of the living space or interior space.

It is an aspect of the process for constructing a three dimensional model of the living space or interior space of a house or building from a floor-plan drawing of the house or building for use in sizing HVAC systems, sizing air ducting systems, or other energy modeling for the house or building to include the process for creating a real-time tabulation or matrix of exterior surface data of the three-dimensional model of the living space or interior space of a house or building for use in sizing HVAC systems, air ducting systems, or other energy modeling for the house or building using imaginary “building blocks” that are scalable cuboids and/or scalable triangular prisms to completely fill in the living space or interior space to create the overall three-dimensional model of the living space or interior space.

### BRIEF DESCRIPTION OF THE DRAWINGS

FIG. 1 is view of the example floor plan that is used in this patent application to demonstrate the process for constructing a three dimensional model of the living space or interior space of a house or building from a floor-plan drawing of the house or building for use in sizing HVAC systems, sizing air ducting systems, or other energy modeling for the house or building.

FIG. 2 is a depiction of the example floor plan, as displayed on the computer screen.

FIG. 2A is the real-time tabulation or matrix of exterior surface data of the three-dimensional model of the living space or interior space of a house or building associated with FIG. 2.

FIG. 2B is a depiction of the example floor plan indicating the Front, Left, Back, and Right directions.

FIG. 3 is a depiction of the first scalable cuboid positioned in the large room on the example floor plan, as displayed on the computer screen.

FIG. 3A is the real-time tabulation or matrix of exterior surface data of the three-dimensional model of the living space or interior space of a house or building associated with FIG. 3.

FIG. 3B is a depiction of the first scalable cuboid indicating wall numbers 1-4, ceiling number 1, and floor number 1.

FIG. 4 is a depiction of the sizing or re-sizing the first scalable cuboid in one dimension of the large room on the example floor plan, as displayed on the computer screen.

FIG. 4A is the real-time tabulation or matrix of exterior surface data of the three-dimensional model of the living space or interior space of a house or building associated with FIG. 4.

FIG. 5 is a depiction of the sizing or re-sizing the first scalable cuboid in a second dimension of the large room on the example floor plan, as displayed on the computer screen.

FIG. 5A is the real-time tabulation or matrix of exterior surface data of the three-dimensional model of the living space or interior space of a house or building associated with FIG. 5.

FIG. 6 is a depiction of the second scalable cuboid positioned on the example floor plan, as displayed on the computer screen.

FIG. 6A is the real-time tabulation or matrix of exterior surface data of the three-dimensional model of the living space or interior space of a house or building associated with FIG. 6.

FIG. 6B is a depiction of the second scalable cuboid indicating wall numbers 5-8, ceiling number 2, and floor number 2.

FIG. 7 is a depiction of the second scalable cuboid positioned to align with the walls of the small room on the example floor plan, as displayed on the computer screen.

FIG. 7A is the real-time tabulation or matrix of exterior surface data of the three-dimensional model of the living space or interior space of a house or building associated with FIG. 7.

FIG. 8 is a depiction of the sizing or re-sizing the second scalable cuboid in one dimension of the small room on the example floor plan, as displayed on the computer screen.

FIG. 8A is the real-time tabulation or matrix of exterior surface data of the three-dimensional model of the living space or interior space of a house or building associated with FIG. 8.

FIG. 9 is a depiction of the sizing or re-sizing the second scalable cuboid in a second dimension of the small room on the example floor plan, as displayed on the computer screen.

FIG. 9A is the real-time tabulation or matrix of exterior surface data of the three-dimensional model of the living space or interior space of a house or building associated with FIG. 9.

FIG. 10 is a depiction of the third scalable cuboid positioned on the example floor plan, as displayed on the computer screen.

FIG. 10A is the real-time tabulation or matrix of exterior surface data of the three-dimensional model of the living space or interior space of a house or building associated with FIG. 10.

FIG. 10B is a depiction of the third scalable cuboid indicating wall numbers 9-12, ceiling number 3, and floor number 3.

FIG. 11 is a depiction of the third scalable cuboid positioned to align with the walls of the open area or unfilled area of the small room, as displayed on the computer screen.

FIG. 11A is the real-time tabulation or matrix of exterior surface data of the three-dimensional model of the living space or interior space of a house or building associated with FIG. 11.

FIG. 12 is a depiction of the sizing or re-sizing the third scalable cuboid in one dimension of the open area or unfilled area of the small room, as displayed on the computer screen.

FIG. 12A is the real-time tabulation or matrix of exterior surface data of the three-dimensional model of the living space or interior space of a house or building associated with FIG. 12.

FIG. 13 is a depiction of the sizing or re-sizing the third scalable cuboid in a second dimension of the open area or unfilled area of the small room, as displayed on the computer screen.

FIG. 13A is the real-time tabulation or matrix of exterior surface data of the three-dimensional model of the living space or interior space of a house or building associated with FIG. 13.

FIG. 14 is a depiction of the first scalable triangular prism positioned on the example floor plan, as displayed on the computer screen.

FIG. 14A is the real-time tabulation or matrix of exterior surface data of the three-dimensional model of the living space or interior space of a house or building associated with FIG. 14.

FIG. 14B is a depiction of the first scalable triangular prism indicating wall numbers 13-15, ceiling number 4, and floor number 4.

FIG. 15 is a depiction of the first scalable triangular prism positioned to align with the walls of the open area or unfilled area of the small room, as displayed on the computer screen.

FIG. 15A is the real-time tabulation or matrix of exterior surface data of the three-dimensional model of the living space or interior space of a house or building associated with FIG. 15.

FIG. 16 is a depiction of the sizing or re-sizing the first scalable triangular prism in one dimension of the open area or unfilled area of the small room, as displayed on the computer screen.

FIG. 16A is the real-time tabulation or matrix of exterior surface data of the three-dimensional model of the living space or interior space of a house or building associated with FIG. 16.

FIG. 17 is a depiction of the sizing or re-sizing the first scalable triangular prism in a second dimension of the open area or unfilled area of the small room, as displayed on the computer screen.

FIG. 17A is the real-time tabulation or matrix of exterior surface data of the three-dimensional model of the living space or interior space of a house or building associated with FIG. 17.

FIG. 18 is a depiction of the second scalable triangular prism positioned on the example floor plan, as displayed on the computer screen.

FIG. 18A is the real-time tabulation or matrix of exterior surface data of the three-dimensional model of the living space or interior space of a house or building associated with FIG. 18.

FIG. 18B is a depiction of the second scalable triangular prism indicating wall numbers 16-18, ceiling number 5, and floor number 5.

FIG. 19 is a depiction of the second scalable triangular prism after being rotated to align with the walls of the last open area or unfilled area of the small room, as displayed on the computer screen.

FIG. 19A is the real-time tabulation or matrix of exterior surface data of the three-dimensional model of the living space or interior space of a house or building associated with FIG. 19.

FIG. 19B is a depiction of FIG. 19 indicating wall numbers 13-15, ceiling number 5, and floor number 5.

FIG. 20 is a depiction of the second scalable triangular prism positioned to align with the walls of the last open area or unfilled area of the small room, as displayed on the computer screen.

FIG. 20A is the real-time tabulation or matrix of exterior surface data of the three-dimensional model of the living space or interior space of a house or building associated with FIG. 20.

FIG. 21 is a depiction of the sizing or re-sizing the second scalable triangular prism in one dimension of the last open area or unfilled area of the small room, as displayed on the computer screen.

FIG. 21A is the real-time tabulation or matrix of exterior surface data of the three-dimensional model of the living space or interior space of a house or building associated with FIG. 21.

FIG. 22 is a depiction of the sizing or re-sizing the second scalable triangular prism in a second dimension of the last open area or unfilled area of the small room, as displayed on the computer screen.

FIG. 22A is the real-time tabulation or matrix of exterior surface data of the three-dimensional model of the living space or interior space of a house or building associated with FIG. 22.

FIG. 23 is a depiction all contiguous scalable cuboids and/or scalable triangular prisms in the small room being grouped together to create one large room, as displayed on the computer screen.

FIG. 23A is the real-time tabulation or matrix of exterior surface data of the three-dimensional model of the living space or interior space of a house or building associated with FIG. 23.

FIG. 23B is a depiction of FIG. 23 indicating room numbers 1 and 2.

FIG. 24 is a depiction of the first ceiling box positioned on the example floor plan, as displayed on the computer screen.

FIG. 24A is the real-time tabulation or matrix of exterior surface data of the three-dimensional model of the living space or interior space of a house or building associated with FIG. 24.

FIG. 24B is a depiction of the first ceiling box indicating wall numbers 19-21 and ceiling number 6.

FIG. 25 is a depiction of the first ceiling box rotated to align with the vaulted ceiling as specified on the example floor plan, as displayed on the computer screen.

FIG. 25A is the real-time tabulation or matrix of exterior surface data of the three-dimensional model of the living space or interior space of a house or building associated with FIG. 25.

FIG. 25B is a depiction of FIG. 25 indicating wall numbers 19-21 and ceiling number 6.

FIG. 26 is a depiction of the sizing or re-sizing the first ceiling box in one dimension, as displayed on the computer screen.

FIG. 26A is the real-time tabulation or matrix of exterior surface data of the three-dimensional model of the living space or interior space of a house or building associated with FIG. 26.

FIG. 27 is a depiction of the sizing or re-sizing the first ceiling box in a second dimension, as displayed on the computer screen.

FIG. 27A is the real-time tabulation or matrix of exterior surface data of the three-dimensional model of the living space or interior space of a house or building associated with FIG. 27.

FIG. 28 is a depiction all contiguous scalable cuboids and/or scalable triangular prisms in the large room being grouped together to create one large room, as displayed on the computer screen.

FIG. 28A is the real-time tabulation or matrix of exterior surface data of the three-dimensional model of the living space or interior space of a house or building associated with FIG. 28.

FIG. 28B is a depiction of FIG. 28 indicating room numbers 1 and 2.

FIG. 29 is a depiction the addition of five windows as specified by the example floor plan, as displayed on the computer screen.

FIG. 29A is the real-time tabulation or matrix of exterior surface data of the three-dimensional model of the living space or interior space of a house or building associated with FIG. 29.

FIG. 29B is a depiction of FIG. 29 indicating window numbers 1-5.

FIG. 30 is a depiction the addition of one door as specified by the example floor plan, as displayed on the computer screen.

FIG. 30A is the real-time tabulation or matrix of exterior surface data of the three-dimensional model of the living space or interior space of a house or building associated with FIG. 30.

FIG. 30B is a depiction of FIG. 30 indicating door number 1.

### DETAILED DESCRIPTION OF THE INVENTION

The process for constructing a three dimensional model of the living space or interior space of a house or building from a floor-plan drawing of the house or building for use in sizing HVAC systems, sizing air ducting systems, or other energy modeling for the house or building is a process or method that is conducted by a special piece of software on a computer. Software is defined as a collection of data or instructions that tell a computer what to do. The special piece of software of this invention will hereafter be described as the software or said software. The software is used to build a three-dimensional model of the living space or interior space of a house or building that is constructed by adding a plurality of scalable cuboids and/or scalable triangular prisms, one by one, and joining them together, to create a complex overall three-dimensional model of the living space or interior space of a house or building. The software also keeps a real-time tabulation or matrix of exterior surface data of the three-dimensional model of the living space or interior space of a house or building. The tabulation or matrix of exterior surface data of the end result three-dimensional model is then entered into a prior art software package to determine the optimum size of HVAC system and/or the optimum size and structure of air ductwork or ducting.

First a computer with a keyboard, a screen or monitor, and a mouse or track pad, used to direct a cursor on the screen or monitor, is obtained wherein the software of this invention is properly installed and functioning on this computer. Next, a floor plan drawing of a house or building with dimensions of all walls and specifications of all doors and all windows is obtained. Optionally, the floor plan may include a north arrow or other indicator of the direction of north. Optionally, the floor plan may include the location of the house or building. A set of floor plan drawings must be obtained that includes a two-dimensional floor plan of each floor of the house or building. A two-story house or building typically has two floor plan drawings or two figure pages, one drawing or figure for each story. Floor plans are typically created in Portable Document Format or PDF file format or other digital file format. If not already in a digital file format, each floor plan or view must be rendered into a digital file format such as PDF, JPG, PNG, or any other type of digital file format. Then the digital file or files are uploaded into the software on the computer.

The number of floors or stories noted on the floor plan must be entered into the software through the keyboard, mouse, or track pad. The floor thickness of each floor noted on the floor plan must be entered into the software through the keyboard, mouse, or track pad. The wall height of each floor noted on the floor plan must be entered into the software through the keyboard, mouse, or track pad. The ceiling height or plate height noted on the floor plan must be entered into the software through the keyboard, mouse, or track pad. The front, left, back, and right sides of the floor plan must be entered into the software through the keyboard, mouse, or track pad.

The imported floor plan must be scaled for width where the cursor is directed or placed on an edge or corner of a wall running along the width on the floor plan and pressing or clicking said mouse or said track pad, then directing and placing the cursor on the opposite edge or corner of the wall running along the width of said house or building and pressing or clicking or releasing said mouse or said track pad, and entering the dimension and the units of the wall running along the width of said house or building as noted on the floor plan through the keyboard.

The imported floor plan must be scaled for length wherein the cursor is directed of placed on an edge or corner of a wall running along the length on said floor plan and pressing or clicking said mouse or said track pad, then directing and placing said cursor on the opposite edge or corner of said wall running along the length of said house or building and pressing or clicking or releasing said mouse or said track pad, and entering the dimension and the units of the wall running along the length of said house or building as noted on the floor plan through the keyboard.

Optionally, the direction of North as indicated on imported floor plan may be entered into the software through the keyboard, mouse, or track pad. Optionally, the location or region of the house or building may be entered into the software through the keyboard, mouse, or track pad. This data is not required to determine or build the three-dimensional model of the living space or interior space of a house or building. This data is required by the prior art software packages to determine the optimum size of HVAC system and/or the optimum size and structure of air ductwork or ducting. In order for seamless transition between this software and the prior art software, information must be entered into the software of this invention.

Next, the three-dimensional model of the living space or interior space of a house or building is constructed by adding scalable cuboids and/or scalable triangular prisms, one by one, and joining them together, to create a complex overall three-dimensional model of the living space or interior space of a house or building. A scalable cuboid is a cuboid or hollow cube shaped member with six sides, four corners, and 12 edges. A scalable cuboid may be scaled to any desired size by selecting one of its edges or corners with the cursor, using the mouse or track pad, and moving the edge or corner to expand or contract the edge or corner, to increase or decrease its size. When this occurs all other members of the scalable cuboid retain their proportionality and change size to coincide with the edge or corner selected by the cursor. When the desired size is obtained, the mouse or track pad is released to leave the edge or corner at this new location, thereby sizing or re-sizing the scalable cuboid. This resizing may be repeated as necessary. A scalable triangular prism is a triangular prism shaped member or three-sided prism shaped member with five sides, six corners, and nine edges. A scalable triangular prism may be scaled to any desired size by selecting one of its edges or corners with the cursor, using the mouse or track pad, and moving the edge or corner to expand or contract the edge or corner, to increase or decrease its size. When this occurs all other members of the scalable triangular prism retain their proportionality and change size to coincide with the edge or corner selected by the cursor. When the desired size is obtained, the mouse or track pad is released to leave the edge or corner at this new location, thereby sizing or re-sizing the scalable triangular prism. This resizing may be repeated as necessary.

In order to build the three-dimensional model of the living space or interior space of a house or building, the user “fills in” each room noted on each floor of the imported floor plan with one or more scalable cuboids and/or one or more scalable triangular prisms so that all rooms are completely filled with the scalable cuboids and/or scalable triangular prisms. There must be exact alignment of these members. All interior surfaces of each scalable cuboid and scalable triangular prism must be coincident with the contiguous surface of their neighboring scalable cuboid or scalable triangular prism, so that there are no gaps or overlap between any scalable cuboids and/or scalable triangular prisms. All exterior surfaces of each scalable cuboid and scalable triangular prism are coincident with the contiguous surface of the corresponding wall, ceiling, or floor of the floor plan so that there are no gaps or overlap between any scalable cuboids and/or scalable triangular prisms and the floor plan. Typically, the three-dimensional model of the living space or interior space of a house or building is started with the lowest floor and built up, floor by floor, to the attic or roof.

The three-dimensional model is made with one or more room boxes and one or more ceiling boxes. A room box could be a scalable cuboid or a scalable triangular prism. All the rooms of a floor or a floor plan are filled with room boxes. A ceiling box could be a scalable cuboid or a scalable triangular prism. Any ceiling space above all of the rooms on a floor or floor plan must also be filled with one or more scalable cuboids and/or one or more scalable triangular prisms.

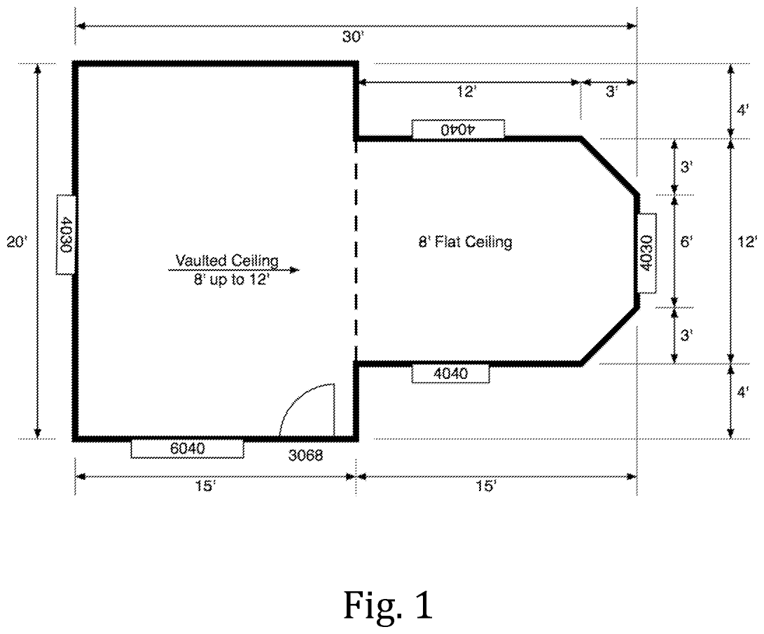

In order to describe how to fill in each room on a floor of the imported floor plan with one or more scalable cuboids and/or one or more scalable triangular prisms, the reader is taken through an example process to build a three-dimensional model of the living space or interior space of a house or building from an example floor plan drawing to determine the surface area and description of each segment of the overall exterior surface of the three-dimensional model. In the following instructional example, a special example floor plan is used that requires the use of scalable cuboids and scalable triangular prisms to construct the three dimensional model, while many floor plans only require the use of scalable cuboids. This example floor plan is depicted in FIG. 1. As with any typical floor plan drawing, the example floor plan drawing includes dimensions of walls and the product codes or description codes of all windows and doors, wherein these product codes or description codes are standard or conventional codes that describe the size and thermal rating of each window and door. Dimensions and product codes or description codes must be present on a floor plan for the software to function properly.

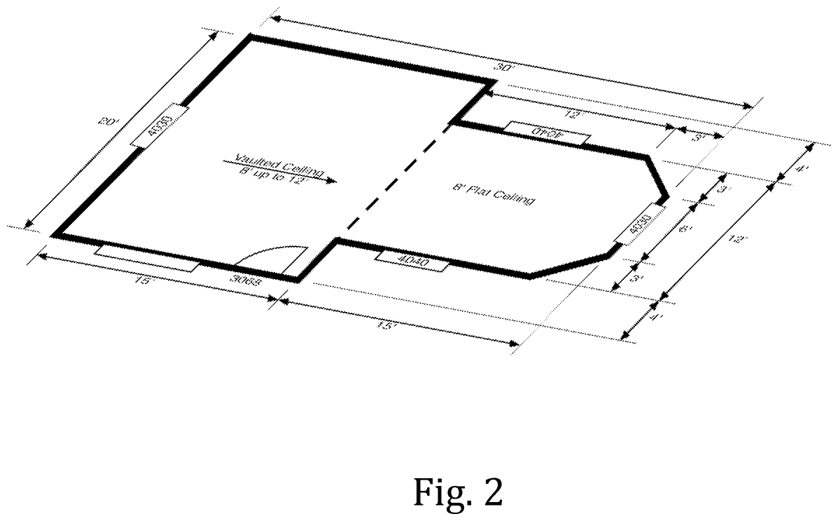

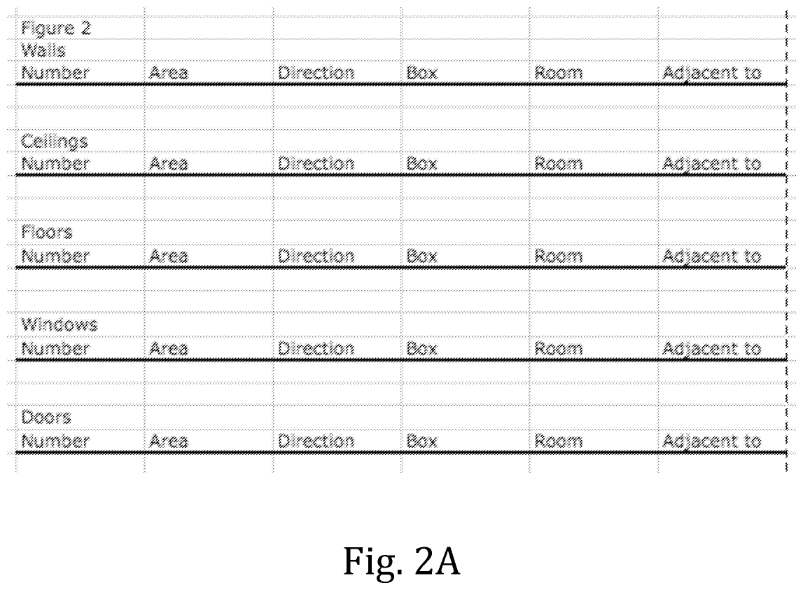

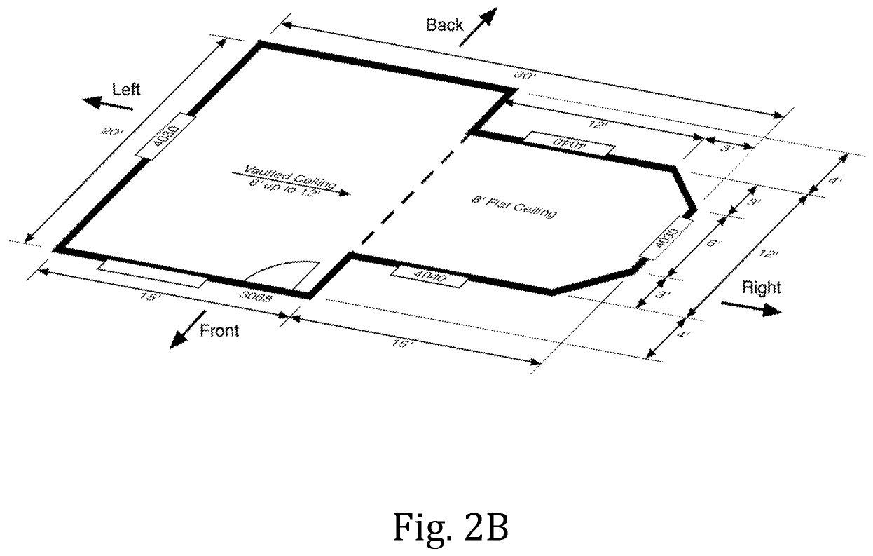

The example floor plan is called up to display on the screen or monitor of the computer. FIG. 2 depicts how the example floor plan would appear on the computer screen.

FIG. 2A represents the real-time tabulation or matrix of exterior surface data of the three-dimensional model of the living space or interior space of a house or building. This real-time tabulation or matrix is empty at this point because no scalable cuboids or scalable triangular prisms have been created yet.

Next, the three-dimensional model of the living space or interior space of a house or building is constructed by adding a plurality of scalable cuboids and/or scalable triangular prisms, one by one, and joining them together, to create a complex overall three-dimensional model of the living space or interior space of a house or building.

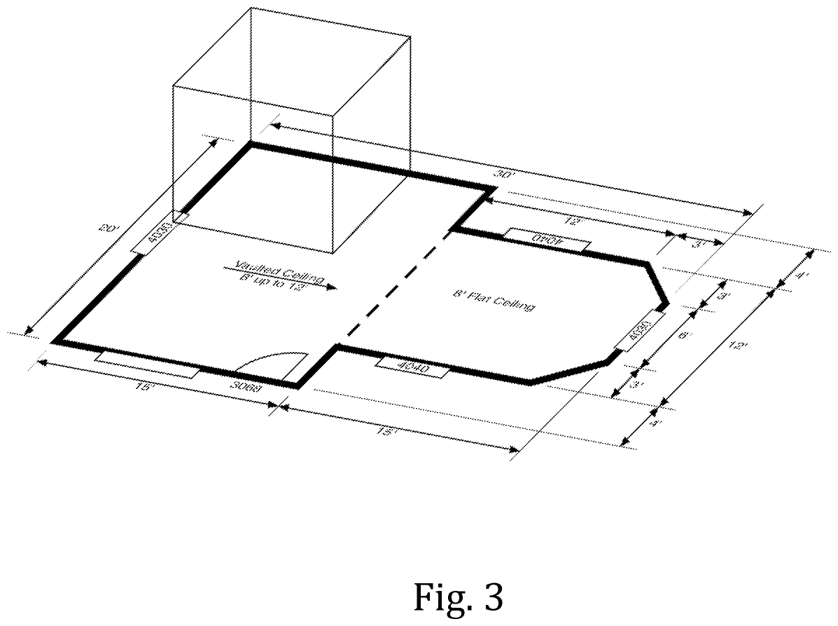

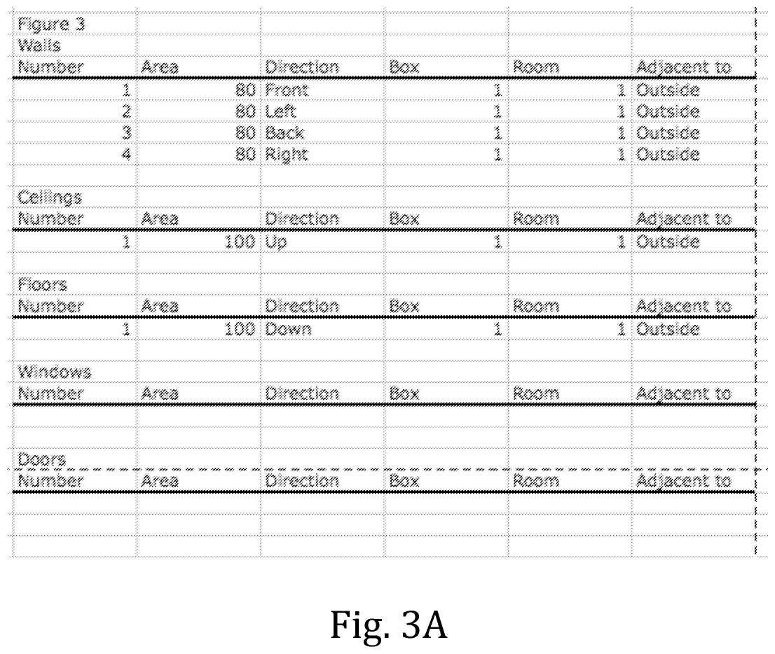

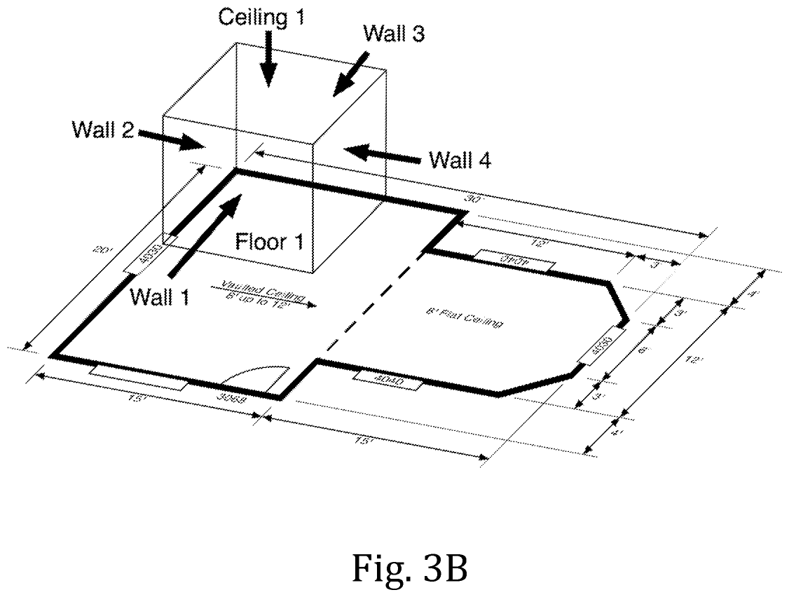

To start this process, the first scalable cuboid is created and positioned in the large room on the example floor plan. One method to create a scalable cuboid in the software is to: enter a command in the software through the keyboard, mouse, or track pad, and position the cursor over a corner of the large room, and press or click the mouse, or track pad to create a scalable cuboid aligned with a corner of the large room, as depicted in FIG. 3. Each scalable cuboid is created in a default size that may be adjusted. Each scalable cuboid is created with four wall surfaces, a ceiling surface, a floor surface, four corners, and 12 edges. Wall surfaces are vertical. Ceiling and floor surfaces are horizontal. The first scalable cuboid is depicted in FIG. 3 as it would appear on the computer screen.

FIG. 3A represents the real-time tabulation or matrix of exterior surface data of the three-dimensional model of the living space or interior space of a house or building. The real-time tabulation or matrix of exterior surface data is the data used by the prior art software to calculate the optimum size of HVAC system and/or the optimum size and structure of air ductwork or ducting.

The real-time tabulation or matrix of exterior surface data includes: 1) the number of exterior walls or exterior wall segments of the three-dimensional model and a description of each wall or wall segment, 2) the number of exterior ceilings or exterior ceiling segments of the three-dimensional model and a description of each ceiling or ceiling segment, 3) the number of exterior floors or exterior floor segments of the three-dimensional model and a description of each floor or floor segment, 4) the number of exterior windows of the three-dimensional model and a description of each window, and 5) the number of exterior doors of the three-dimensional model and a description of each door. The description of each segment includes: 1) a designation number, 2) total surface area, 3) direction segment is facing, 4) box number, 5) room number, and 6) “adjacent to” field. The process for keeping a real-time tabulation or matrix of exterior surface data of the living space or interior space of a house or building constructed by adding a plurality of scalable cuboids and/or scalable triangular prisms to fill in the entire the living space or interior space of a house or building is novel and non-obvious.

At this point, the three-dimensional model of the living space or interior space of a house or building is just the one scalable cuboid. The first scalable cuboid is box number 1. This real-time tabulation or matrix of exterior surface data in FIG. 3A indicates that there are four walls, one ceiling, one floor, zero windows, and zero doors.

The wall number of the four walls is designated as 1-4, consecutively. The surface area of each of the four walls is indicated as 80 square feet. The direction of the four walls is indicated as Front, Left, Back, and Right, consecutively. The box number of each of the four walls is indicated as 1. The room number of each of the four walls is indicated as 1. The Adjacent to field of each of the four walls is designated as Outside.

The ceiling number of the ceiling is designated as 1. The surface area of ceiling number 1 is indicated as 100 square feet. The direction of ceiling number 1 is indicated as Up. The box number of ceiling number 1 is indicated as 1. The room number of ceiling number 1 is indicated as 1. The Adjacent to field of the ceiling is designated as Outside.

The floor number of the floor is designated as 1. The surface area of floor number 1 is indicated as 100 square feet. The direction of floor number 1 is indicated as Down. The box number of floor number 1 is indicated as 1. The room number of floor number 1 is indicated as 1. The Adjacent to field of the floor is designated as Outside.

The adjacent code is a description of what is adjacent to or contiguous with each wall, ceiling, or floor. In this case, the adjacent code of all is “Outside” because this is the first cuboid or prism and they are no other cuboids or prisms that are adjacent or contiguous with the four sides, ceiling, and floor of this cuboid. The adjacent code may be toggled from “outside” to “condition space” which would convert the side from an exterior side to an interior side. As stated, all interior sides become a part of the interior of the three dimensional model of the living space or interior space of a house or building.

Since there are no windows yet, the window section of the real-time tabulation or matrix of exterior surface data is empty. Since there are no doors yet, the door section of the real-time tabulation or matrix of exterior surface data is empty.

Next, the first scalable cuboid must be sized and exactly positioned to align and coincide with the walls of the target room to be filled, in this case, the large room, by re-sizing the length and the width of the scalable cuboid and/or re-locating the entire scalable cuboid to align and coincide with the walls of the large room.

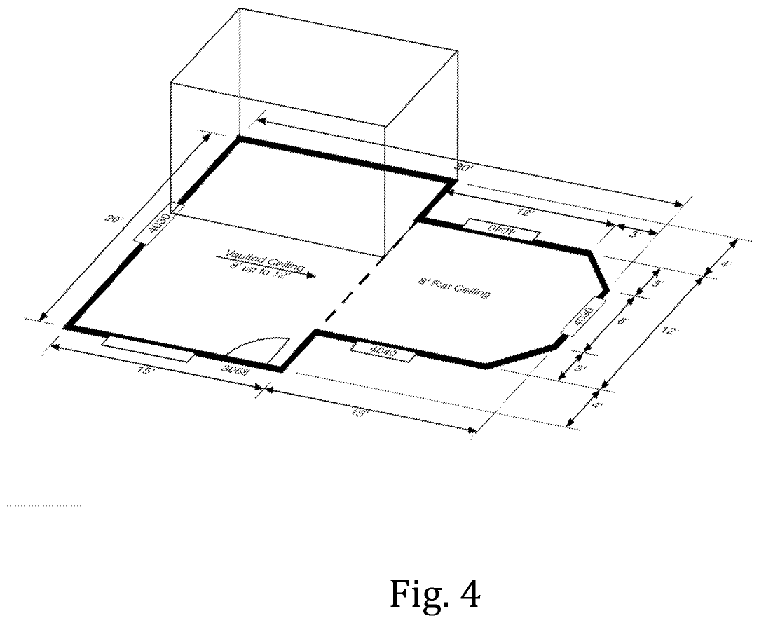

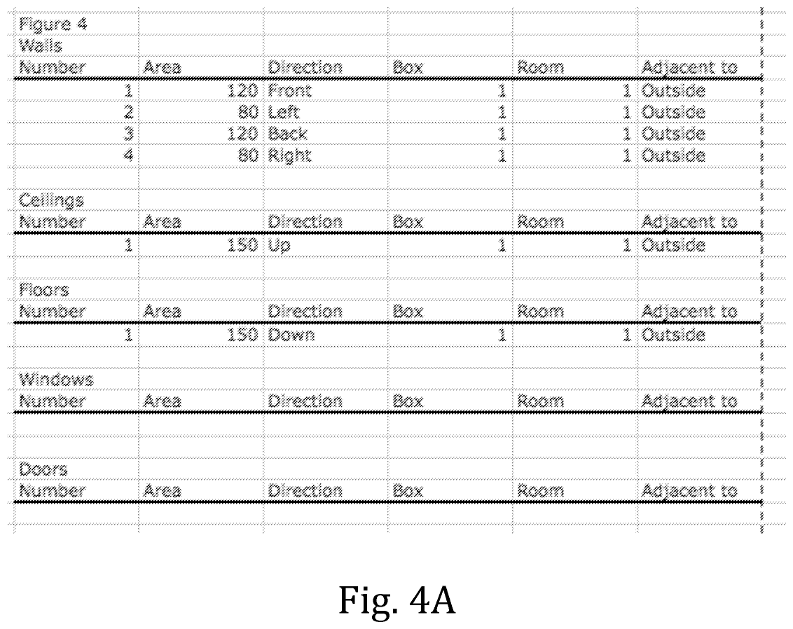

One method to accomplish this with the software is to select one of the edges or corners of the first scalable cuboid not yet in alignment with the floor plan, using the mouse or track pad, and stretching or moving it to exactly align with and coincide with the corresponding edge or corner of the room being filled, at which time the mouse or track pad is clicked or released to leave the edge or corner at this new location, thereby sizing or re-sizing the first scalable cuboid in one dimension, which would be the length or width dimension of the room. Note that the height dimension of the room was already set by entering the wall height of each floor as stated above. The action of sizing or re-sizing the first scalable cuboid in one dimension is depicted in FIG. 4.

FIG. 4A represents the real-time tabulation or matrix of exterior surface data of the new size, showing that wall numbers 3 and 4 increased in surface area from 80 to 120 square feet, ceiling number 1 increased in surface area from 100 to 150 square feet, and floor number 1 increased in surface area from 100 to 150 square feet, while the surface areas of wall numbers 2 and 4 stayed the same at 80 square feet.

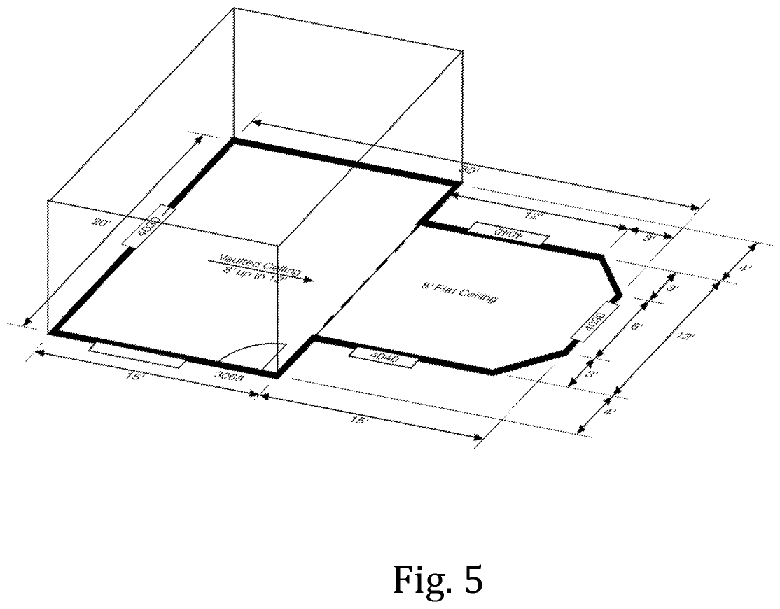

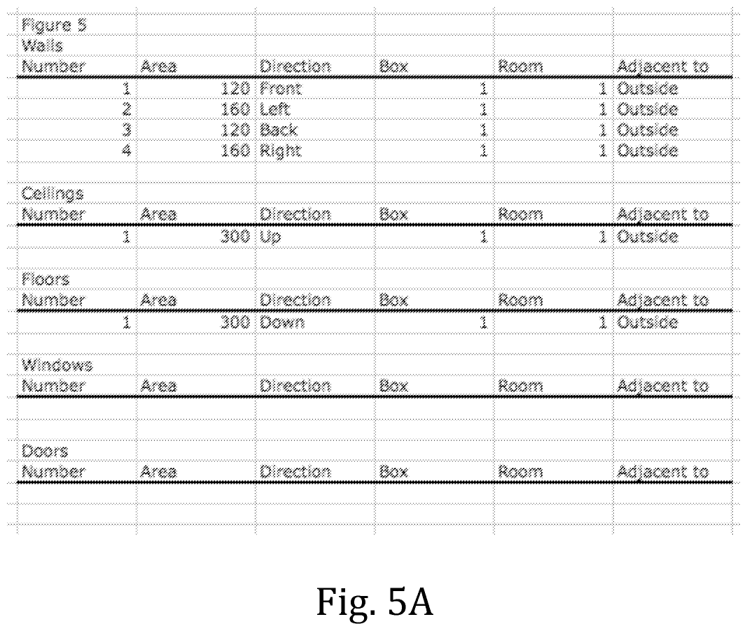

Next, one of the remaining edges or corners of the first scalable cuboid not yet in alignment with the floor plan is selected by the cursor, using the mouse or track pad, and stretched or moved to exactly align with and coincide with the corresponding edge or corner of the room, at which time the mouse or track pad is clicked or released to leave the edge or corner at this new location, thereby sizing or re-sizing the first scalable cuboid in last dimension, which would be the length or width of the room. Note that the length of the scalable cuboid could be sized first or the width could be sized first; it does not matter. The action of sizing or re-sizing the first scalable cuboid in the last dimension is depicted in FIG. 5.

FIG. 5A represents the real-time tabulation or matrix of exterior surface data of the new size, showing that wall numbers 2 and 4 increased in surface area from 80 to 160 square feet, wall numbers 3 and 4 kept the same surface area at 120 square feet, ceiling number 1 increased in surface area from 150 to 300 square feet, and floor number 1 increased in surface area from 150 to 300 square feet.

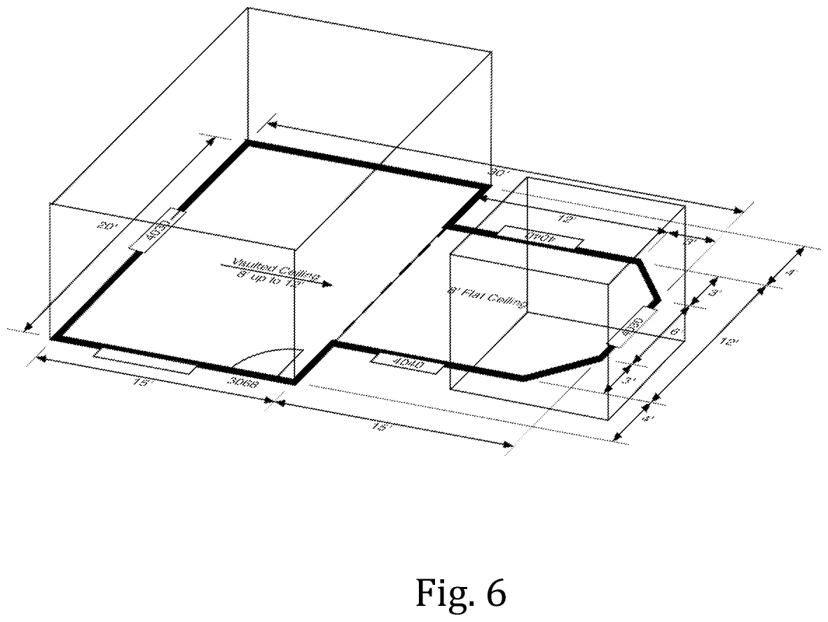

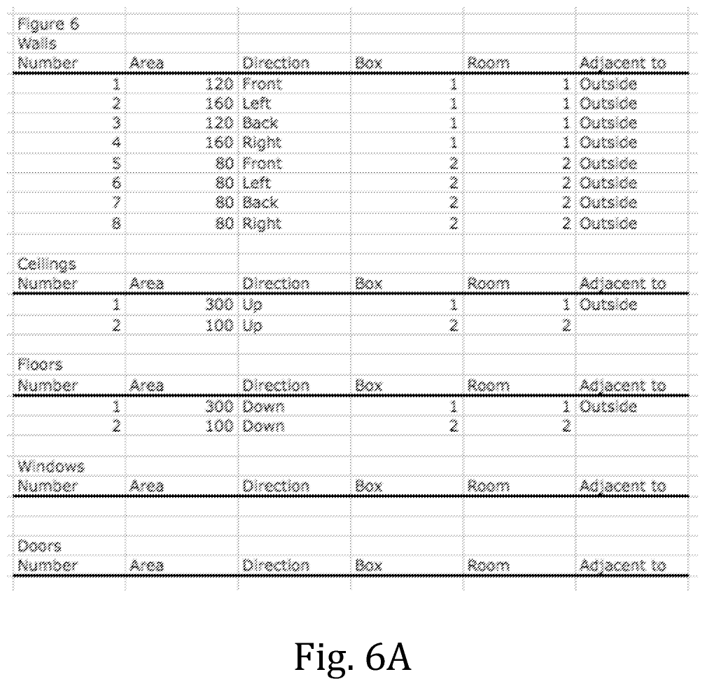

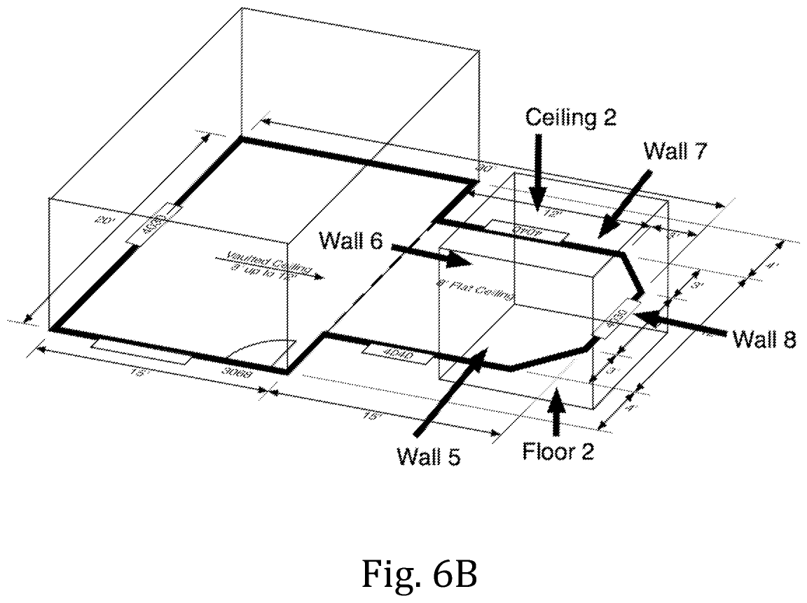

Next, the second scalable cuboid is created and positioned on the example floor plan, as depicted in FIG. 6. The second scalable cuboid is box number 2. One method to create a scalable cuboid in the software is to: enter a command in the software through the keyboard, mouse, or track pad to create a scalable cuboid in random position on the screen, as depicted in FIG. 6.

The creation of the second scalable cuboid changes the real-time tabulation or matrix of exterior surface data by adding four walls designated as wall numbers 5-8, consecutively. The surface area of each of the four walls is indicated as 80 square feet. The direction of the four walls is indicated as Front, Left, Back, and Right, consecutively. The box number of each of the four walls is indicated as 2. The room number of each of the four walls is indicated as 2. The Adjacent to field of each of the four walls is designated as Outside.

The creation of the second scalable cuboid changes the real-time tabulation or matrix of exterior surface data by adding a ceiling designated as ceiling number 2. The surface area of ceiling number 2 is indicated as 100 square feet. The direction of ceiling number 2 is indicated as Up. The box number of ceiling number 2 is indicated as 2. The room number of ceiling number 2 is indicated as 2. The Adjacent to field of ceiling number 2 is designated as Outside.

The creation of the second scalable cuboid changes the real-time tabulation or matrix of exterior surface data by adding a floor designated as floor number 2. The surface area of floor number 2 is indicated as 100 square feet. The direction of floor number 2 is indicated as Up. The box number of floor number 2 is indicated as 2. The room number of floor number 2 is indicated as 2. The Adjacent to field of floor number 2 is designated as Outside.

FIG. 6A represents the real-time tabulation or matrix of exterior surface data of the three-dimensional model of the living space or interior space of a house or building depicted in FIG. 6, showing that: four more walls were created with wall numbers 5-8, each having a surface area of 80 square feet, each belonging to box number 2 and room number 2; one more ceiling was created with ceiling number 2, having a surface area of 100 square feet, belonging to box number 2 and room number 2; and one more floor was created with floor number 2, having a surface area of 100 square feet, belonging to box number 2 and room number 2.

Next, the second scalable cuboid must be sized and exactly positioned to align and coincide with the walls of the target room to be filled, in this case, the small room, by re-sizing the length and the width of the scalable cuboid and/or re-locating the entire scalable cuboid to align and coincide with the walls of the small room.

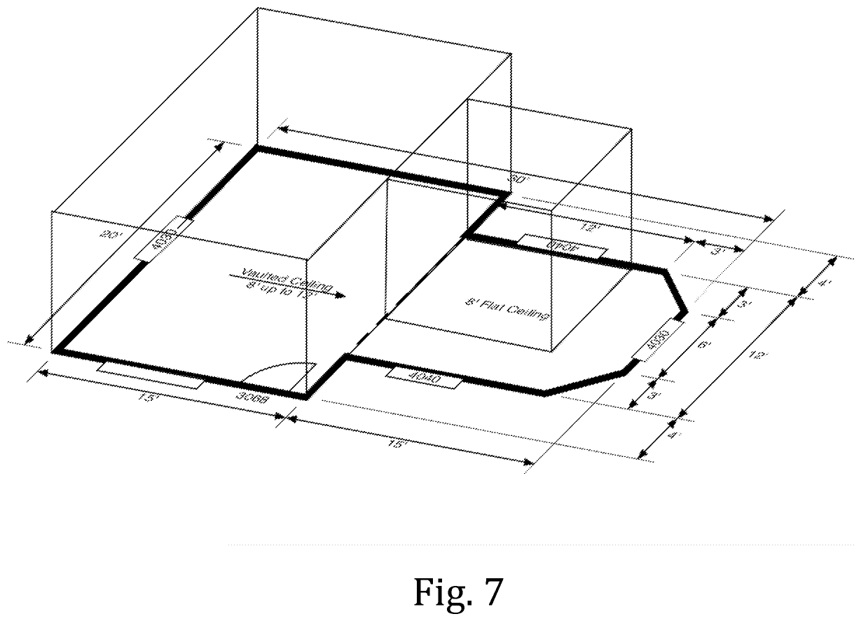

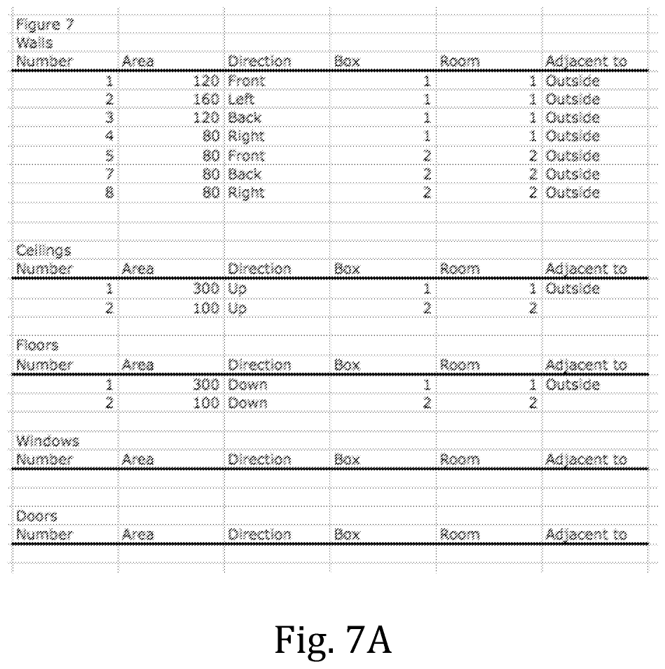

One method to accomplish this with the software is to select the whole second scalable cuboid, using the mouse or track pad, and locating or relocating the whole second scalable cuboid to align and coincide with a corner of the small room, at which time the mouse or track pad is clicked or released to deselect the whole second scalable cuboid to leave it at this new location in alignment with a corner of the room. In best mode, there is a “collide and snap” mechanism or function in the software, where one scalable cuboid and/or scalable triangular prism will not pass through another, where the two walls of each scalable cuboid and/or scalable triangular prism collide with each other and then snap onto each other to effectuate an automatic alignment between the two colliding walls. This is depicted in FIG. 7.

Whenever placing scalable cuboids and/or scalable triangular prisms next to each other, they must be positioned or located to exactly align and coincide with each other, without any gaps there between. In best mode, this software includes an automatic check function where the software will automatically check for walls, ceilings, and floors that are very close to each other but are not quite perfectly aligned to coincide with each other and will highlight these segments so that the user can check to be sure that this is what they really meant to draw and allow the user to adjust or move scalable cuboids and/or scalable triangular prisms as necessary.

Note that by moving the second scalable cuboid to the corner of the small room, the entire wall number 6 of the second scalable cuboid is now coincident with part of wall number 4 in the first scalable cuboid. The software of this invention recognizes this coincidence of interior walls of different scalable cuboids and reacts by rendering the coincident section of the walls as non-existent and renders the coincident section of walls as open space in the interior of the three dimensional model of the living space or interior space of a house or building. Thus, the entire wall number 6 of the second scalable cuboid is removed from the real-time tabulation or matrix of exterior surface data. Also, the surface area of wall number 4 of the first scalable cuboid is reduced by the surface area of wall number 6 of the second scalable cuboid, which is coincident portion.

FIG. 7A represents the real-time tabulation or matrix of exterior surface data of the three-dimensional model of the living space or interior space of a house or building depicted in FIG. 7, which shows that: wall numbers 1-3 stayed the same; wall number 4 decreased in surface area from 160 to 80 square feet; wall number 6 was deleted; walls 5, 7, and 8 stayed the same; ceiling numbers 1 and 2 stayed the same; and floor numbers 1 and 2 stayed the same.

Note that wall number 4 is now effectively split into two pieces, one piece on either side of the deleted wall number 6. The surface areas of these two pieces of wall number 4 add together to yield the 80 square feet.

Next, the second scalable cuboid must be sized and exactly positioned to align and coincide with all walls of the small room by sizing or re-sizing the length and the width of the scalable cuboid.

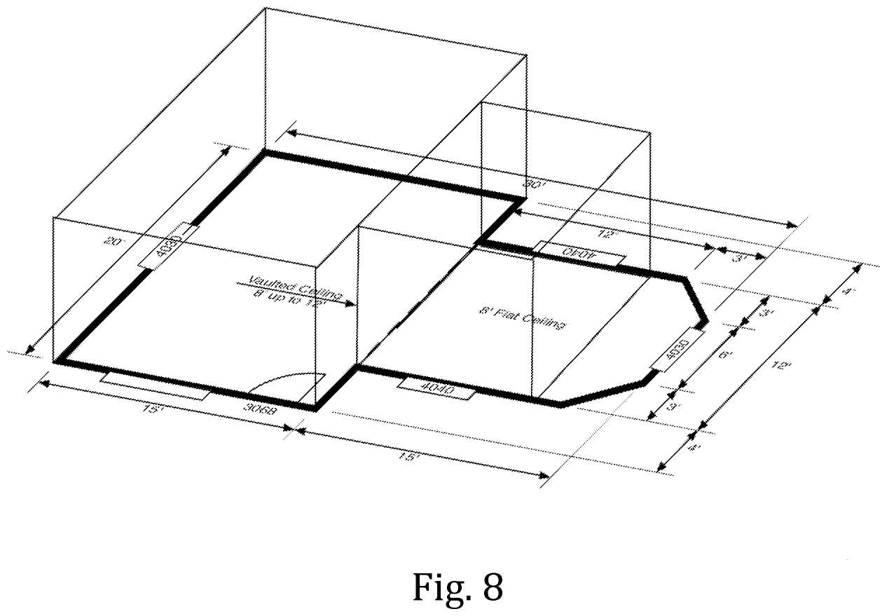

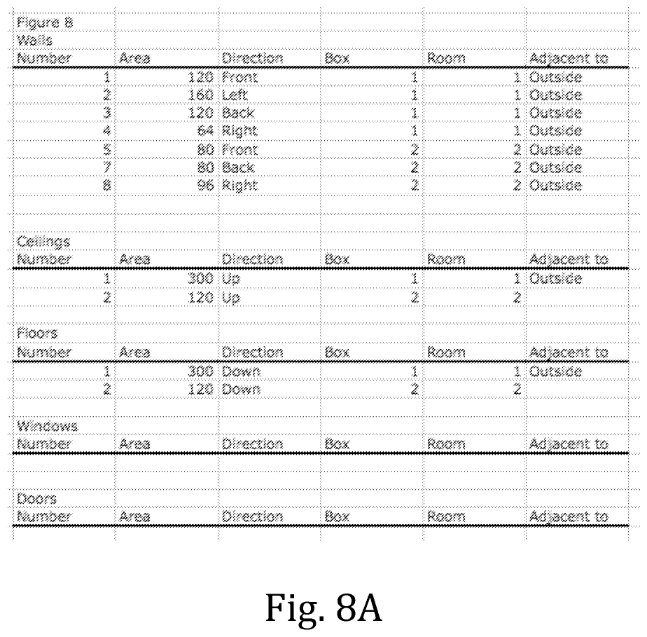

To start this, one of the edges or corners of the second scalable cuboid located within the room is selected by the cursor, using the mouse or track pad, and stretched or moved to exactly align with and coincide with the corresponding edge or corner of the room, at which time the mouse or track pad is released to leave the edge or corner at this new location, thereby sizing or re-sizing the second scalable cuboid in one dimension, which would be the length or width dimension of the room. Note that the height dimension of the room was already set by entering the wall height of each floor as stated above. The action of sizing or re-sizing the first scalable cuboid in one dimension is depicted in FIG. 8.

FIG. 8A represents the real-time tabulation or matrix of exterior surface data of the new size, which shows that: wall numbers 1-3 stayed the same; wall number 4 decreased in surface area from 80 to 64 square feet; wall numbers 5 and 7 stayed the same; wall number 8 increased in surface area from 80 to 96 square feet; ceiling numbers 1 and 2 stayed the same; and floor numbers 1 and 2 increased in surface area from 100 to 120 square feet.

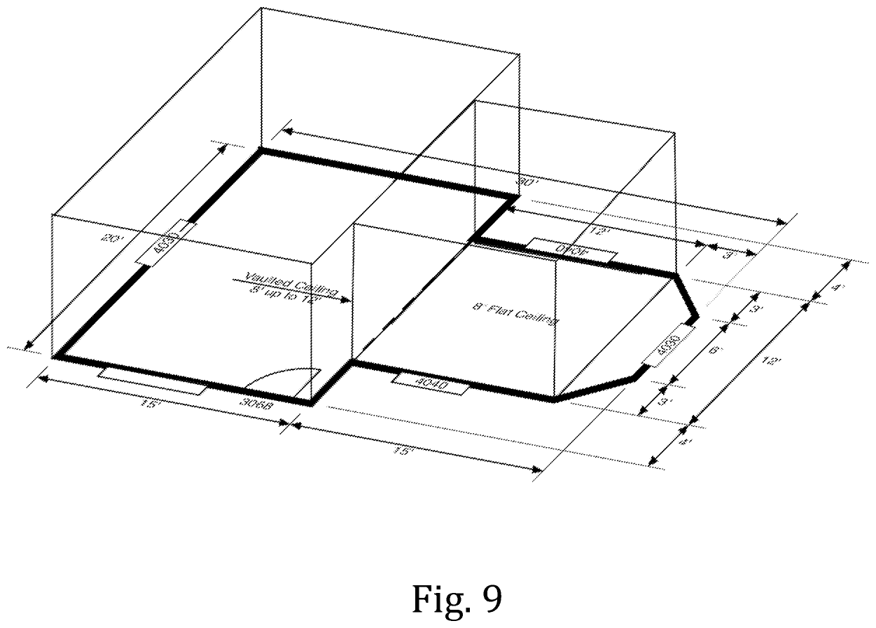

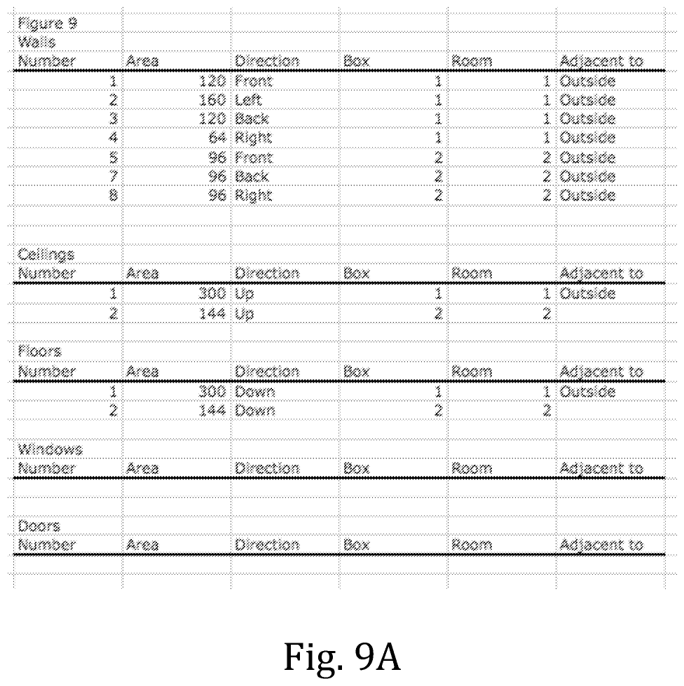

Next, one of the edges or corners of the second scalable cuboid still remaining within the room is selected by the cursor, using the mouse or track pad, and stretched or moved to exactly align with and coincide with the corresponding edge or corner of the room, at which time the mouse or track pad is released to leave the edge or corner at this new location, thereby sizing or re-sizing the second scalable cuboid in last dimension, which would be the length or width of the room. Note that the length of the room could be sized first or the width sized first; it does not matter. The action of sizing or re-sizing the second scalable cuboid in the last dimension is depicted in FIG. 9.

FIG. 9A represents the real-time tabulation or matrix of exterior surface data of the new size, which shows that: wall numbers 1-4 stayed the same; walls number 5 and 7 increased in surface area from 80 to 96 square feet; wall number 8 stayed the same; ceiling numbers 1 and 2 stayed the same; and floor numbers 1 and 2 increased in surface area from 120 to 144 square feet.

As stated, the addition of scalable cuboid number 2 and its alignment with wall number 4 of scalable cuboid 1 has caused the coincident or overlapped sections of scalable cuboids 1 and 2 to disappear or to be deleted. This causes wall number 6 to be completely deleted from the three dimensional model of the living space or interior space of a house or building. This also causes wall number 4 to be broken down into 2 sections of wall, one on each side of deleted wall number 6. Note that the summation of the surface areas of these two sections of wall number 4 is the surface area listed for wall number 4 in the real-time tabulation or matrix of exterior surface data or 64 square feet.

As can be seen in FIG. 9, the second scalable cuboid did not completely fill the small room on the example floor plan. There is an unfilled gap in the small room. Note that the open area or unfilled area of the small room is not square or rectangular shaped. Thus, a third scalable cuboid cannot completely fill this space without any gaps or open areas. In order to completely fill this space without any gaps or open areas, two scalable triangular prisms must be used in addition to the third scalable cuboid.

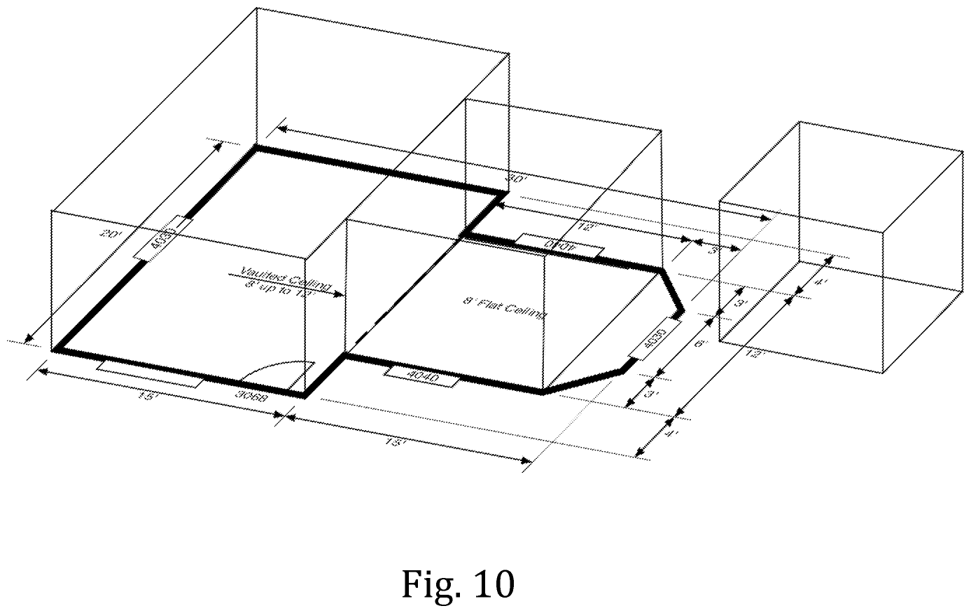

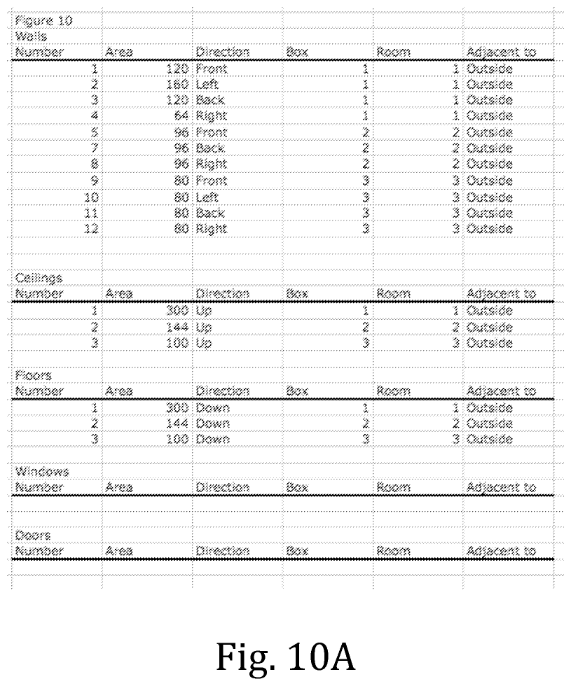

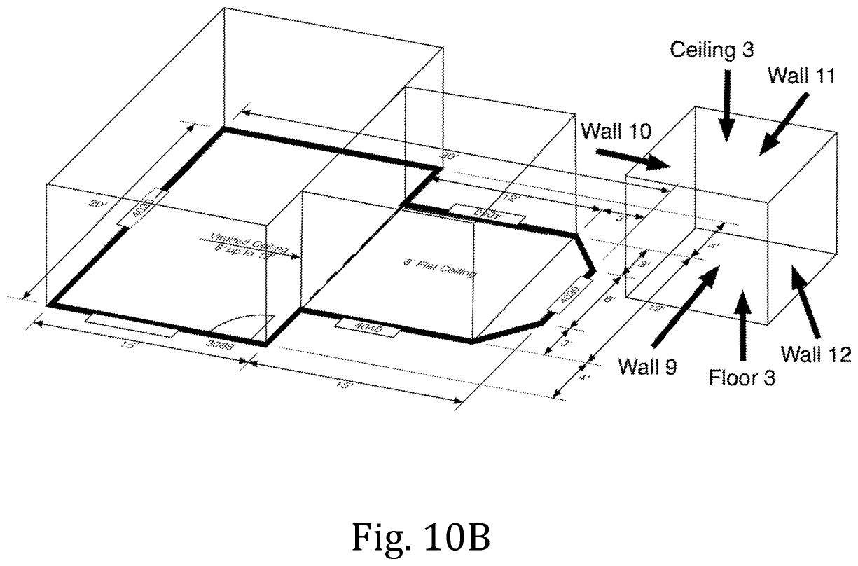

The third scalable cuboid is created and positioned within the example floor plan, as depicted in FIG. 10. The third scalable cuboid is box number 3. To do this, a command is entered into the software through the keyboard, mouse, or track pad to create a scalable cuboid as depicted in FIG. 10.

The creation of the third scalable cuboid changes the real-time tabulation or matrix of exterior surface data by adding four walls designated as wall numbers 9-12, consecutively. The surface area of each of the four walls is indicated as 80 square feet. The direction of the four walls is indicated as Front, Left, Back, and Right, consecutively. The box number of each of the four walls is indicated as 3. The room number of each of the four walls is indicated as 3. The Adjacent to field of each of the four walls is designated as Outside.

The creation of the third scalable cuboid changes the real-time tabulation or matrix of exterior surface data by adding a ceiling designated as ceiling number 3. The surface area of ceiling number 3 is indicated as 100 square feet. The direction of ceiling number 3 is indicated as Up. The box number of ceiling number 3 is indicated as 3. The room number of ceiling number 3 is indicated as 3. The Adjacent to field of ceiling number 3 is designated as Outside.

The creation of the third scalable cuboid changes the real-time tabulation or matrix of exterior surface data by adding a floor designated as floor number 3. The surface area of floor number 3 is indicated as 100 square feet. The direction of floor number 2 is indicated as Up. The box number of floor number 3 is indicated as 3. The room number of floor number 3 is indicated as 3. The Adjacent to field of floor number 3 is designated as Outside.

FIG. 10A represents the real-time tabulation or matrix of exterior surface data of the three-dimensional model of the living space or interior space of a house or building depicted in FIG. 10, showing that: four more walls were created with wall numbers 9-12, each having a surface area of 80 square feet, each belonging to box number 3 and room number 3; one more ceiling was created with ceiling number 3, having a surface area of 100 square feet, belonging to box number 3 and room number 3; and one more floor was created with floor number 3, having a surface area of 100 square feet, belonging to box number 3 and room number 3.

Next, the third scalable cuboid must be sized and exactly positioned to align and coincide with the walls of the target room to be filled, in this case, the open area or unfilled area of the small room, by re-sizing the length and the width of the scalable cuboid and/or re-locating the entire scalable cuboid to align and coincide with the walls of the open area or unfilled area of the small room.

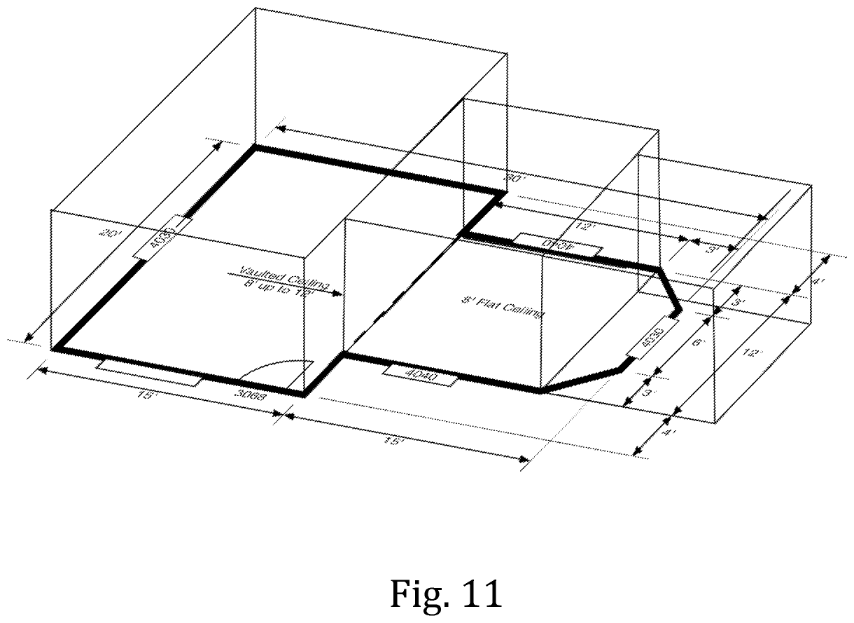

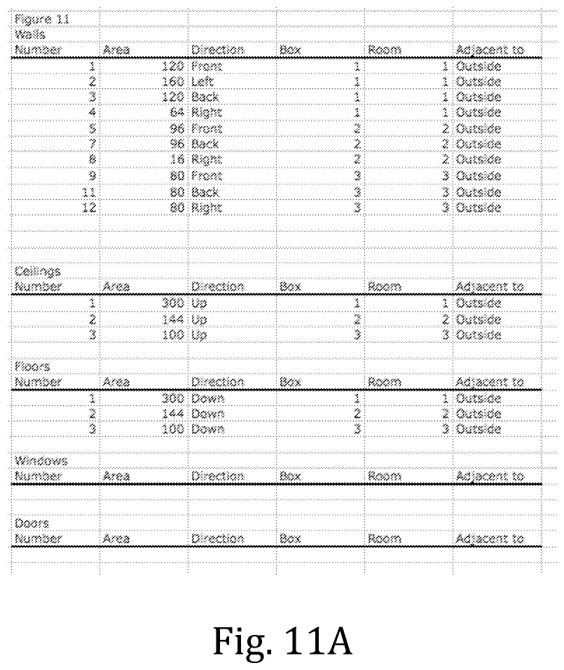

One method to accomplish this with the software is to select the whole third scalable cuboid, using the mouse or track pad, and locating or relocating the whole third scalable cuboid to align and coincide with a corner of the open area or unfilled area of the small room, at which time the mouse or track pad is clicked or released to deselect the whole third scalable cuboid to leave it at this new location in alignment with a corner of the open area or unfilled area of the small room. As stated, in best mode, there is a “collide and snap” mechanism or function in the software, where one scalable cuboid and/or scalable triangular prism will not pass through another, where the two walls of each scalable cuboid and/or scalable triangular prism collide with each other and then snap onto each other to effectuate an automatic alignment between the two colliding walls. This is depicted in FIG. 11.

Whenever placing scalable cuboids and/or scalable triangular prisms next to each other, they must be positioned or located to exactly align and coincide with each other, without any gaps there between.

Note that by moving the third scalable cuboid to align with wall number 8, the entire wall number 10 of the third scalable cuboid is now coincident with part of wall number 8 in the second scalable cuboid. The software of this invention recognizes this coincidence of interior walls of different scalable cuboids and reacts by rendering the coincident section of the walls as non-existent and renders the coincident section of walls as open space in the interior of the three dimensional model of the living space or interior space of a house or building. Thus, the entire wall number 10 of the third scalable cuboid is removed from the real-time tabulation or matrix of exterior surface data. Also, the surface area of wall number 8 of the second scalable cuboid is reduced by the surface area of wall number 8 of the third scalable cuboid, which is coincident portion.

FIG. 11A represents the real-time tabulation or matrix of exterior surface data of the three-dimensional model of the living space or interior space of a house or building depicted in FIG. 11, which shows that: wall numbers 1-4 stayed the same; wall numbers 5 and 7 stayed the same; wall number 8 decreased in surface area from 96 to 16 square feet; wall number 10 was deleted; walls 9, 11, and 12 stayed the same; ceiling numbers 1, 2 and 3 stayed the same; and floor numbers 1, 2, and 3 stayed the same.

Next, the third scalable cuboid is sized and exactly positioned to align and coincide with the rectangular portion of the open or unfilled area in the small room of the floor plan, to leave open spaces for two scalable triangular prisms.

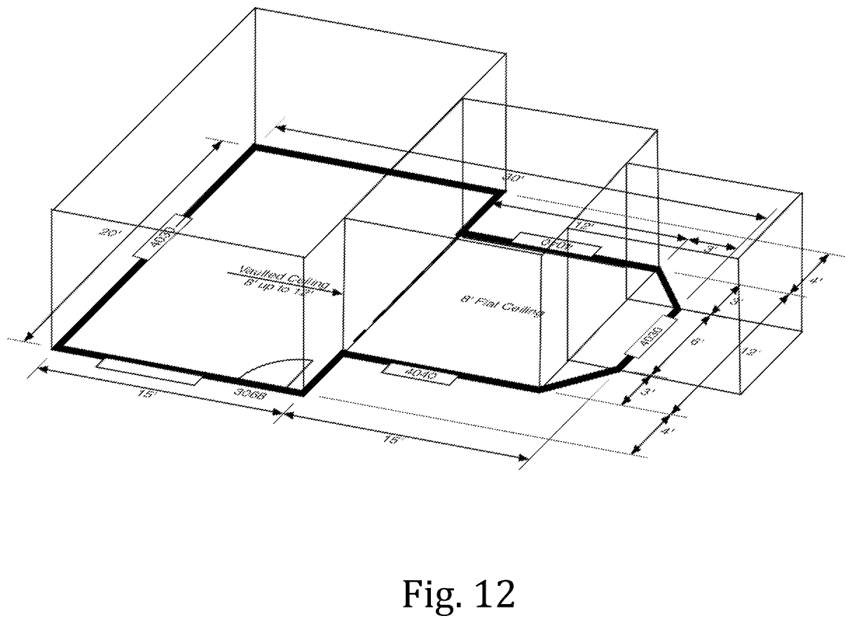

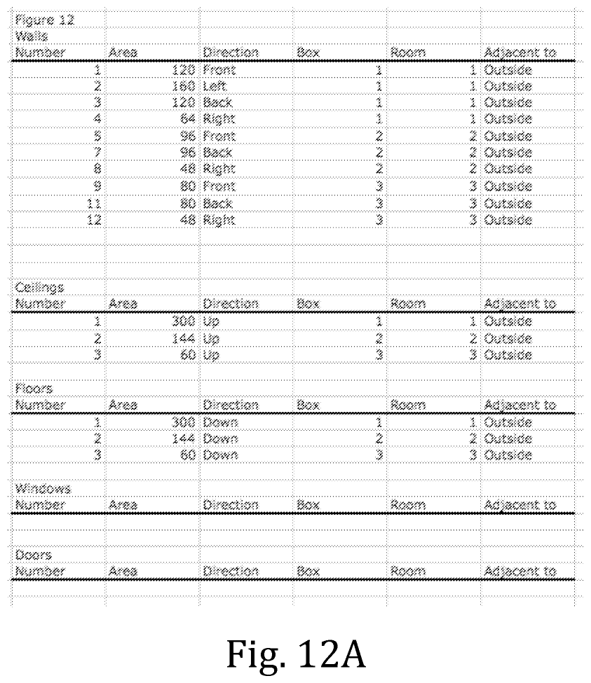

To accomplish this, one of the edges or corners of the third scalable cuboid adjacent to the deleted wall number 10 is selected by the cursor, using the mouse or track pad, and stretched or moved to exactly align with and coincide with the corresponding edge or corner of the rectangular portion of the open or unfilled area in the small room, at which time the mouse or track pad is clicked or released to leave the edge or corner at this new location, thereby sizing or re-sizing the third scalable cuboid in one dimension, which would be the length or width dimension. Next, one of the remaining edges or corners of the third scalable cuboid adjacent to the deleted wall number 10 is selected by the cursor, using the mouse or track pad, and stretched or moved to exactly align with and coincide with the corresponding edge or corner of the rectangular portion of the open or unfilled area in the small room, at which time the mouse or track pad is clicked or released to leave the edge or corner at this new location, thereby sizing or re-sizing the first scalable cuboid in last dimension, which would be the length or width of the room. Note that the length of the scalable cuboid could be sized first or the width could be sized first; it does not matter. The action of sizing or re-sizing the first scalable cuboid in the last dimension is depicted in FIG. 12.

FIG. 12A represents the real-time tabulation or matrix of exterior surface data of the three-dimensional model of the living space or interior space of a house or building depicted in FIG. 12, showing that wall numbers 1-4 stayed the same; wall numbers 5 and 7 stayed the same; wall number 8 increased in surface area from 16 to 48 square feet; wall numbers 9 and 11 stayed the same; wall number 12 decreased in surface area from 80 to 48 square feet; ceiling number 3 decreased in surface area from 100 to 60 square feet; and floor number 3 decreased in surface area from 100 to 60 square feet; ceiling numbers 1 and 2 stayed the same; floor numbers 1 and 2 stayed the same; ceiling number 3 decreased in surface area from 100 to 60 square feet; and floor number 3 decreased in surface area from 100 to 60 square feet. Note that wall number 8 is now effectively split into two pieces, one piece on either side of the deleted wall number 10. The surface areas of these two pieces of wall number 8 add together to yield the 48 square feet.

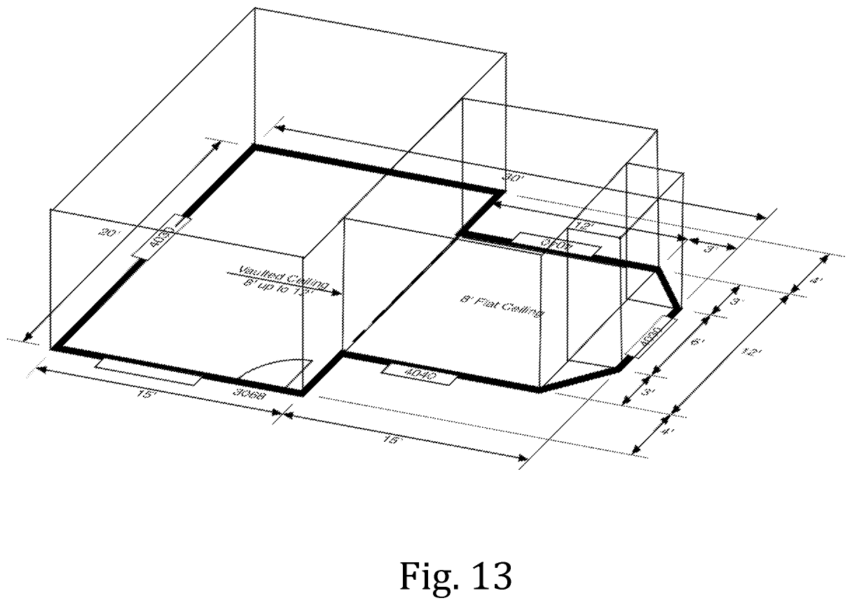

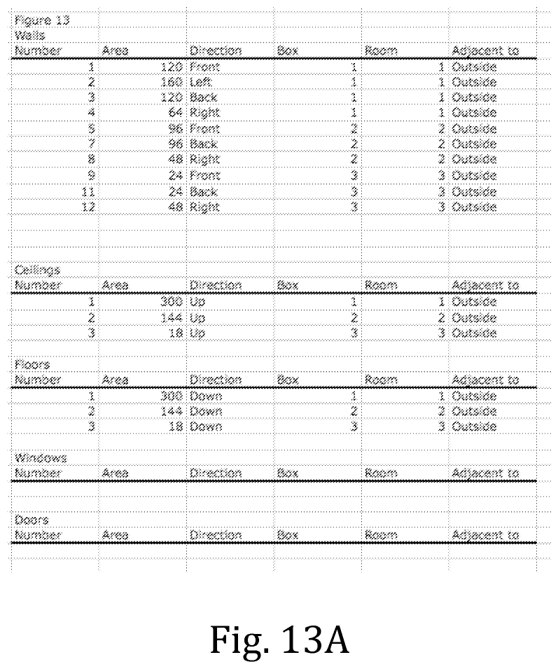

Next, one of the remaining edges or corners of the third scalable cuboid not yet in alignment with the open area or unfilled area of the small room is selected by the cursor, using the mouse or track pad, and stretched or moved to exactly align with and coincide with the corresponding edge or corner of the open area or unfilled area of the small room, at which time the mouse or track pad is clicked or released to leave the edge or corner at this new location, thereby sizing or re-sizing the third scalable cuboid in last dimension, which would be the length or width of the room. The action of sizing or re-sizing the third scalable cuboid in the last dimension is depicted in FIG. 13.

FIG. 13A represents the real-time tabulation or matrix of exterior surface data of the three-dimensional model of the living space or interior space of a house or building depicted in FIG. 13, showing that wall numbers 1-4 stayed the same; wall numbers 5, 7, and 8 stayed the same; wall numbers 9 and 11 stayed the same; wall number 12 decreased in surface area from 80 to 48 square feet; ceiling numbers 1 and 2 stayed the same; floor numbers 1 and 2 stayed the same; ceiling number 3 decreased in surface area from 60 to 18 square feet; and floor number 3 decreased in surface area from 60 to 18 square feet.

Note the two open areas or unfilled areas of the small room that exits at this point. These open areas or unfilled areas will each be filled with a scalable triangular prism.

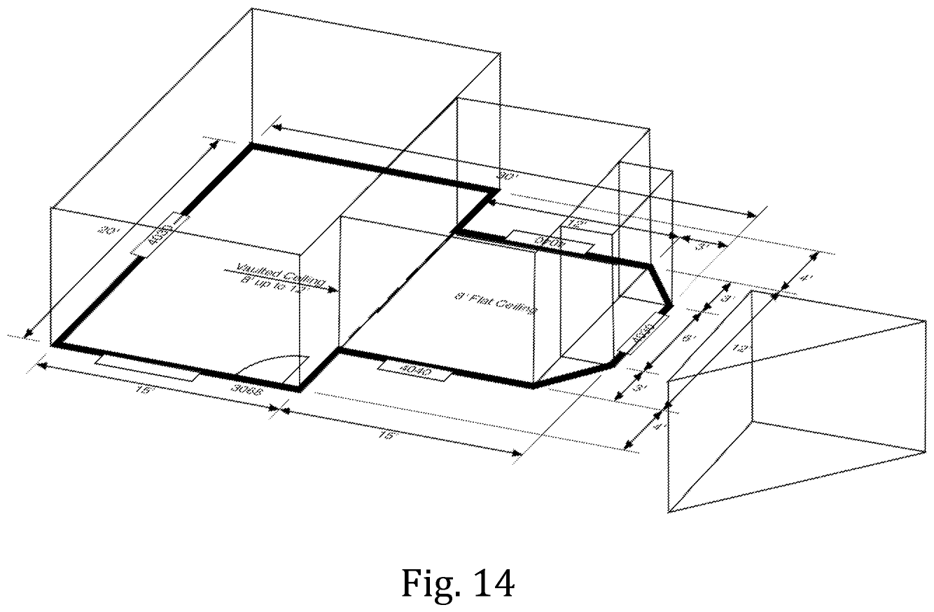

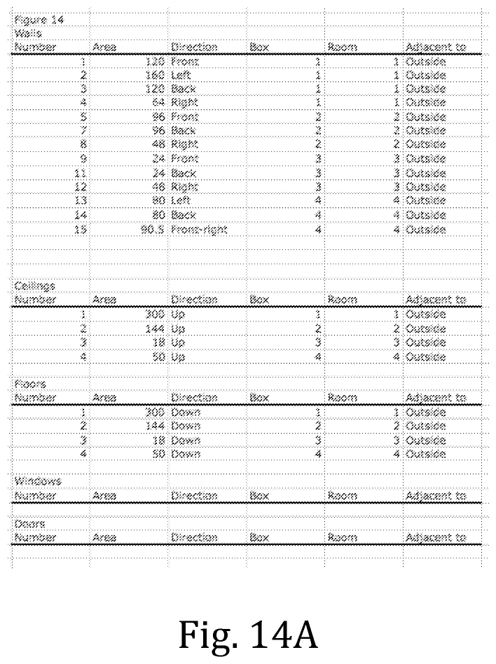

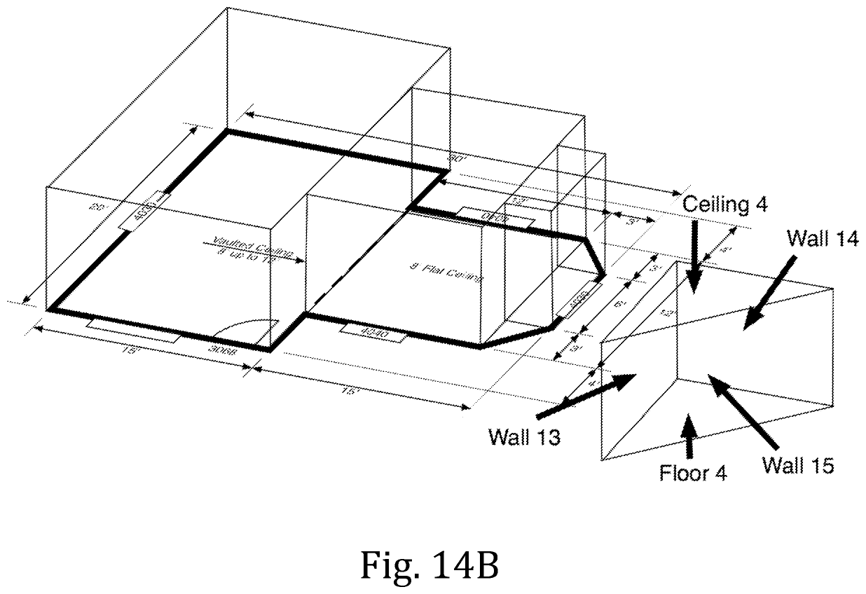

Next, the first scalable triangular prism is created and positioned on the example floor plan. The first scalable triangular prism is box number 4. One method to create a scalable triangular prism in the software is to: enter a command in the software through the keyboard, mouse, or track pad, and position the cursor over a corner of the large room, and press or click the mouse, or track pad to create a scalable triangular prism in random position on the screen. Each scalable triangular prism is created in a default size that may be adjusted. Each scalable triangular prism is created with three wall surfaces, a ceiling surface, a floor surface, six corners, and nine edges. Wall surfaces are vertical. Ceiling and floor surfaces are horizontal. The first scalable triangular prism is depicted in FIG. 14 as it would appear on the computer screen.

The creation of the first scalable triangular prism changes the real-time tabulation or matrix of exterior surface data by adding three walls designated as wall numbers 13-15, consecutively. The surface area of wall numbers 13 and 14 each have a surface area of 80 square feet. Wall number 15 has a surface area of 90.5 square feet. The direction of the three walls is indicated as Left, Back, and Front Right, consecutively. The box number of each of the three walls is indicated as 4. The room number of each of the three walls is indicated as 4. The Adjacent to field of each of the three walls is designated as Outside.

The creation of the first scalable triangular prism changes the real-time tabulation or matrix of exterior surface data by adding a ceiling designated as ceiling number 4. The surface area of ceiling number 4 is indicated as 50 square feet. The direction of ceiling number 2 is indicated as Up. The box number of ceiling number 4 is indicated as 4. The room number of ceiling number 4 is indicated as 4. The Adjacent to field of ceiling number 4 is designated as Outside.

The creation of the first scalable triangular prism changes the real-time tabulation or matrix of exterior surface data by adding a floor designated as floor number 4. The surface area of floor number 4 is indicated as 50 square feet. The direction of floor number 4 is indicated as Up. The box number of floor number 4 is indicated as 4. The room number of floor number 4 is indicated as 4. The Adjacent to field of floor number 4 is designated as Outside.

FIG. 14A represents the real-time tabulation or matrix of exterior surface data of the three-dimensional model of the living space or interior space of a house or building depicted in FIG. 14, showing that: three more walls were created with wall numbers 13-15, with wall numbers 13 and 14 each having a surface area of 80 square feet and wall number 15 having a surface area of 90.5 square feet; each new wall belonging to box number 4 and room number 4; one more ceiling was created with ceiling number 4, having a surface area of 50 square feet, belonging to box number 4 and room number 4; and one more floor was created with floor number 4, having a surface area of 50 square feet, belonging to box number 4 and room number 4.

Next, the first scalable triangular prism must be sized and exactly positioned to align and coincide with the walls of one of the open areas or unfilled areas of the small room by re-sizing the length and the width of the scalable triangular prism and/or re-locating the entire scalable triangular prism to align and coincide with these walls.

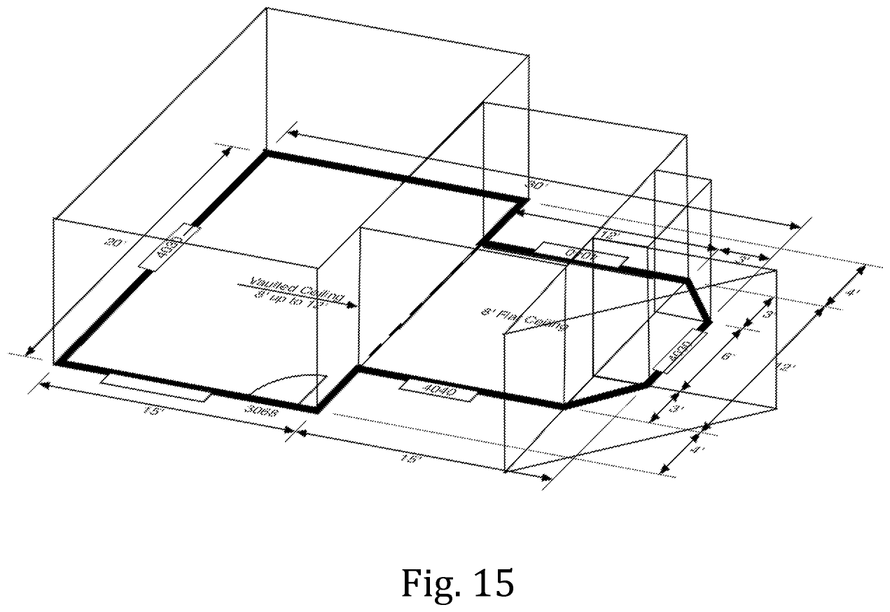

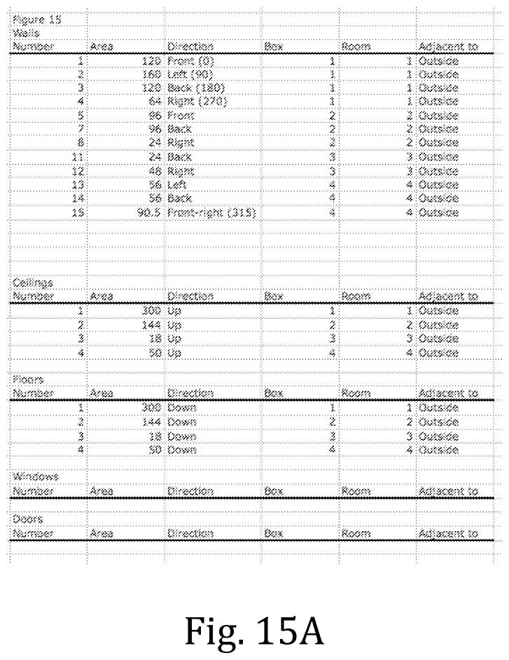

One method to accomplish this with the software is to select the whole first scalable triangular prism, using the mouse or track pad, and locating or relocating the whole first scalable triangular prism to align and coincide with a corner of the open area or unfilled area of the small room, at which time the mouse or track pad is clicked or released to deselect the whole first scalable triangular prism to leave it at this new location in alignment with a corner of the formerly open area or unfilled area. As stated, in best mode, there is a “collide and snap” mechanism or function in the software, where one scalable cuboid and/or scalable triangular prism will not pass through another, where the two walls of each scalable cuboid and/or scalable triangular prism collide with each other and then snap onto each other to effectuate an automatic alignment between the two colliding walls. This is depicted in FIG. 15.

Whenever placing scalable cuboids and/or scalable triangular prisms next to each other, they must be positioned or located to exactly align and coincide with each other, without any gaps there between.

Note that by moving the first scalable triangular prism into the corner of the open area or unfilled area, the entire wall number 9 of the third scalable cuboid is now coincident with part of wall number 13 in the first scalable triangular prism and part of wall number 8 of the second scalable cuboid is now coincident with part of wall number 14 of the first scalable triangular prism. The software of this invention recognizes these coincidences of interior walls of different scalable cuboids and/or scalable triangular prisms, and reacts by rendering the coincident sections of the walls as non-existent and renders the coincident sections of walls as open space in the interior of the three dimensional model of the living space or interior space of a house or building. Thus, the entire wall number 9 of the third scalable cuboid is removed from the real-time tabulation or matrix of exterior surface data. Also, part of wall number 8 of the second scalable cuboid, part of wall number 13 in the first scalable triangular prism, and part of wall number 14 of the first scalable triangular prism are removed from the real-time tabulation or matrix of exterior surface data.

FIG. 15A represents the real-time tabulation or matrix of exterior surface data of the three-dimensional model of the living space or interior space of a house or building depicted in FIG. 15, which shows that: wall numbers 1-4, 5, and 7 stayed the same; wall number 8 decreased in surface area from 48 to 24 square feet; wall number 9 was deleted; wall numbers 11 and 12 stayed the same; wall numbers 13 and 14 decreased in surface area from 80 to 56 square feet; wall 15 stayed the same; ceiling numbers 1-4 stayed the same; and floor numbers 1-4 stayed the same. Note that one of two pieces of wall number 8 is now effectively deleted to leave only one piece left. The surface area of the one piece of wall number 8 is 24 square feet.

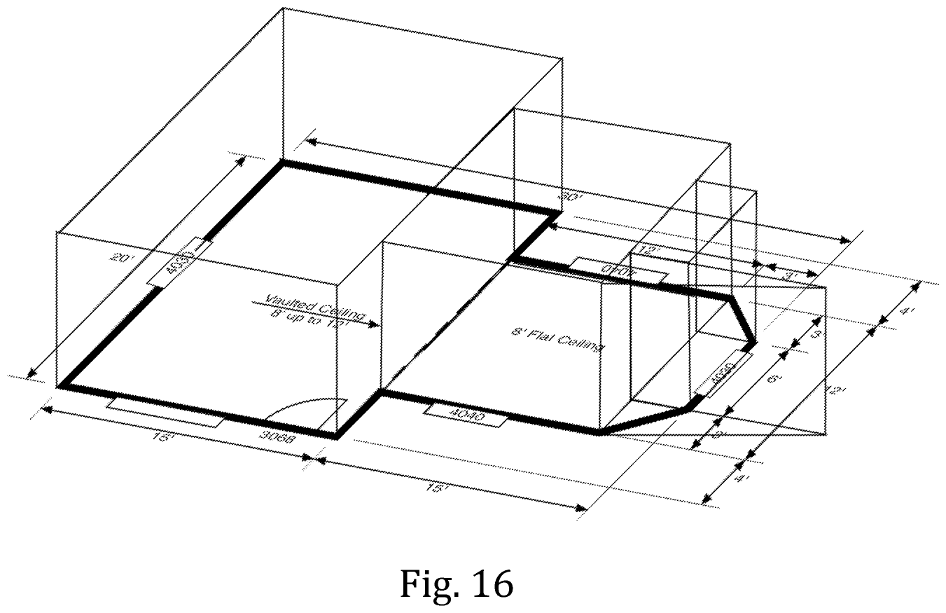

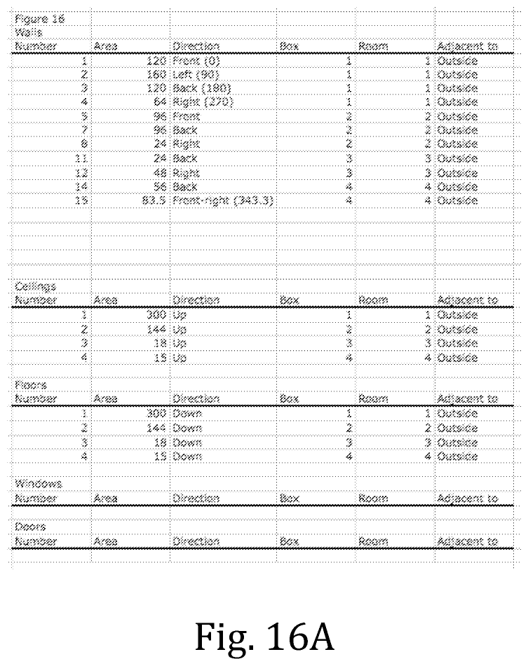

Next, the first scalable triangular prism must be sized and exactly positioned to align and coincide with all walls of the open area or unfilled area of the small room by sizing or re-sizing the length and the width of the scalable triangular prism. This is accomplished by selecting one of the edges or corners of the first scalable triangular prism not yet in alignment with the open area or unfilled area of the small room is selected by the cursor, using the mouse or track pad, and stretching or moving it to exactly align with and coincide with the corresponding edge or corner of the open area or unfilled area of the small room, at which time the mouse or track pad is clicked or released to leave the edge or corner at this new location, thereby sizing or re-sizing the first scalable triangular prism in one dimension, which would be the length or width dimension of the room. The action of sizing or re-sizing the first scalable triangular prism in one dimension is depicted in FIG. 16.

FIG. 16A represents the real-time tabulation or matrix of exterior surface data of the three-dimensional model of the living space or interior space of a house or building depicted in FIG. 16, which shows that: wall numbers 1-5, 7, 8, 11, and 12 stayed the same; wall number 13 was deleted; wall number 14 stayed the same; wall number 15 decreased in surface area from 90.5 to 83.5 square feet; ceiling numbers 1-3 stayed the same; floor numbers 1-3 stayed the same; ceiling number 4 decreased in surface area from 50 to 15 square feet; and floor number 4 decreased in surface area from 50 to 15 square feet.

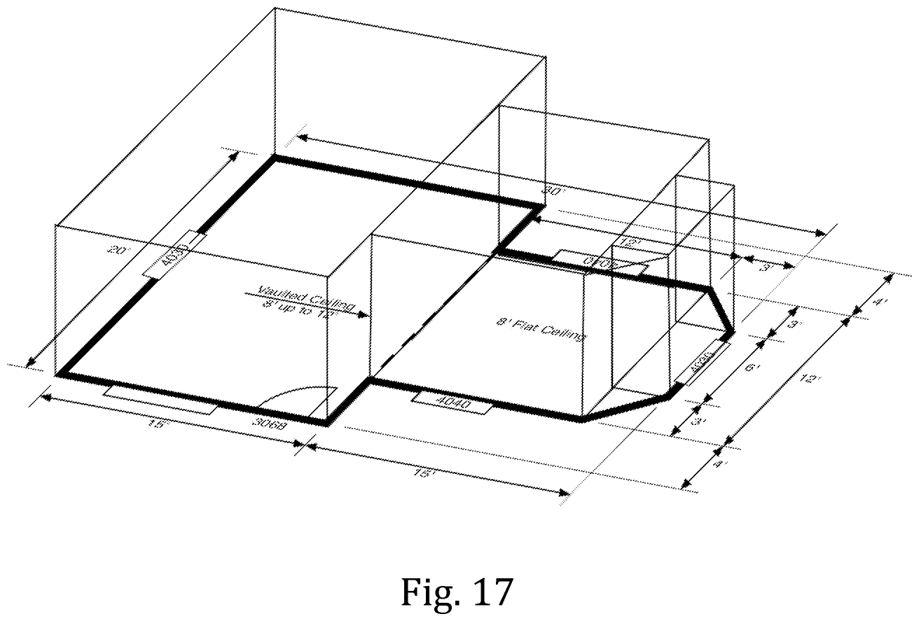

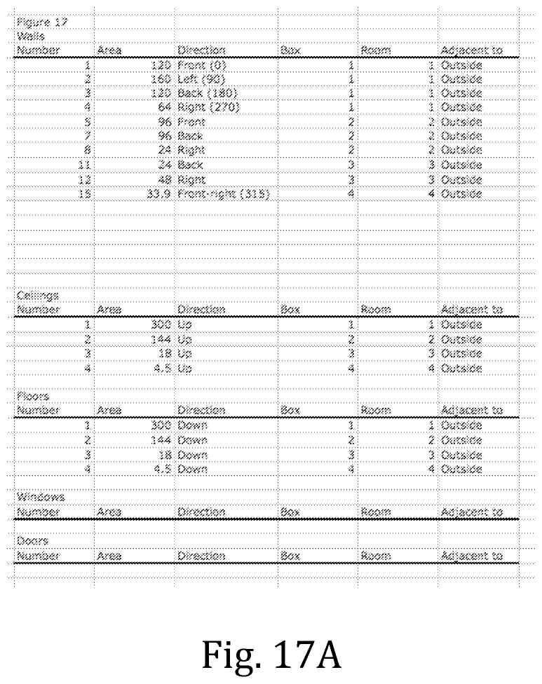

Next, one of the remaining edges or corners of the first scalable triangular prism not yet in alignment with the open area or unfilled area of the small room is selected by the cursor, using the mouse or track pad, and stretched or moved to exactly align with and coincide with the corresponding edge or corner of the open area or unfilled area of the small room, at which time the mouse or track pad is clicked or released to leave the edge or corner at this new location, thereby sizing or re-sizing the first scalable triangular prism in last dimension, which would be the length or width of the room. The action of sizing or re-sizing the first scalable triangular prism in the last dimension is depicted in FIG. 17.

FIG. 17A represents the real-time tabulation or matrix of exterior surface data of the three-dimensional model of the living space or interior space of a house or building depicted in FIG. 17, which shows that: wall numbers 1-5, 7, 8, 11, and 12, stayed the same; wall number 14 was deleted; wall number 15 decreased in surface area from 83.5 to 33.9 square feet; ceiling numbers 1-3 stayed the same; floor numbers 1-3 stayed the same; ceiling number 4 decreased in surface area from 15 to 4.5 square feet; and floor number 4 decreased in surface area from 15 to 4.5 square feet.

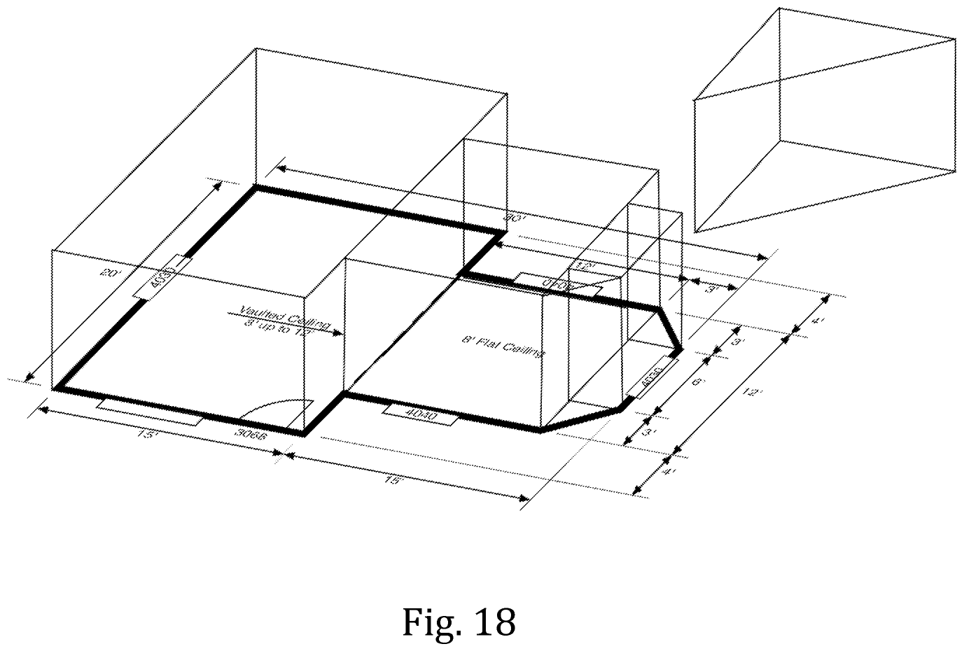

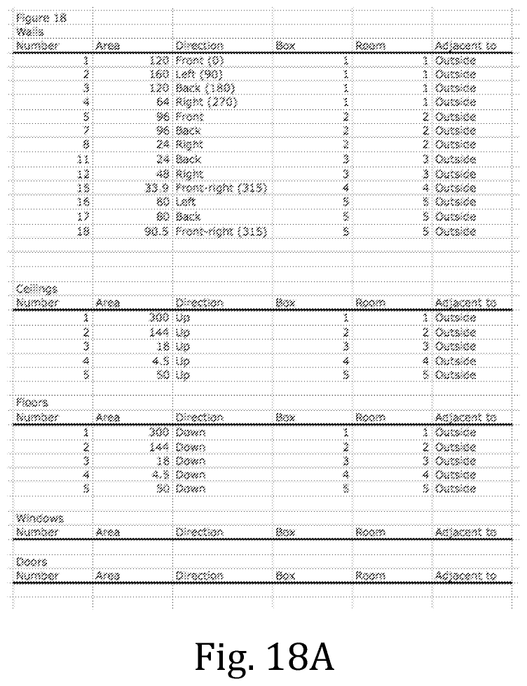

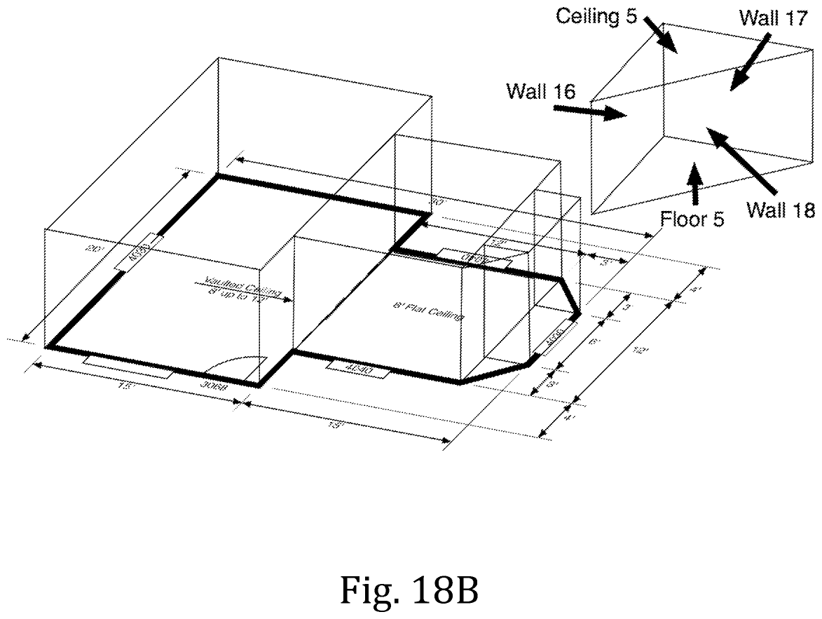

Next, the second scalable triangular prism is created and positioned on the example floor plan. The second scalable triangular prism is box number 5. One method to create a scalable triangular prism in the software is to: enter a command in the software through the keyboard, mouse, or track pad, and position the cursor over a corner of the large room, and press or click the mouse, or track pad to create a scalable triangular prism in random position on the screen. Each scalable triangular prism has three wall surfaces, a ceiling surface, a floor surface, six corners, and nine edges. Wall surfaces are vertical. Ceiling and floor surfaces are horizontal. The second scalable triangular prism is depicted in FIG. 18 as it would appear on the computer screen.

The creation of the second scalable triangular prism changes the real-time tabulation or matrix of exterior surface data by adding three walls designated as wall numbers 16-18, consecutively. The surface area of wall numbers 16 and 17 each have a surface area of 80 square feet. Wall number 18 has a surface area of 90.5 square feet. The direction of the three walls is indicated as Left, Back, and Front Right, consecutively. The box number of each of the three walls is indicated as 5. The room number of each of the three walls is indicated as 5. The Adjacent to field of each of the three walls is designated as Outside.

The creation of the second scalable triangular prism changes the real-time tabulation or matrix of exterior surface data by adding a ceiling designated as ceiling number 5. The surface area of ceiling number 5 is indicated as 50 square feet. The direction of ceiling number 2 is indicated as Up. The box number of ceiling number 5 is indicated as 5. The room number of ceiling number 5 is indicated as 5. The Adjacent to field of ceiling number 4 is designated as Outside.

The creation of the second scalable triangular prism changes the real-time tabulation or matrix of exterior surface data by adding a floor designated as floor number 5. The surface area of floor number 5 is indicated as 50 square feet. The direction of floor number 5 is indicated as Up. The box number of floor number 5 is indicated as 5. The room number of floor number 5 is indicated as 5. The Adjacent to field of floor number 5 is designated as Outside.

FIG. 18A represents the real-time tabulation or matrix of exterior surface data of the three-dimensional model of the living space or interior space of a house or building depicted in FIG. 18, showing that: three more walls were created with wall numbers 16-18, with wall numbers 16 and 17 each having a surface area of 80 square feet and wall number 18 having a surface area of 90.5 square feet; each new wall belonging to box number 5 and room number 5; one more ceiling was created with ceiling number 5, having a surface area of 50 square feet, belonging to box number 5 and room number 5; and one more floor was created with floor number 5, having a surface area of 50 square feet, belonging to box number 5 and room number 5.

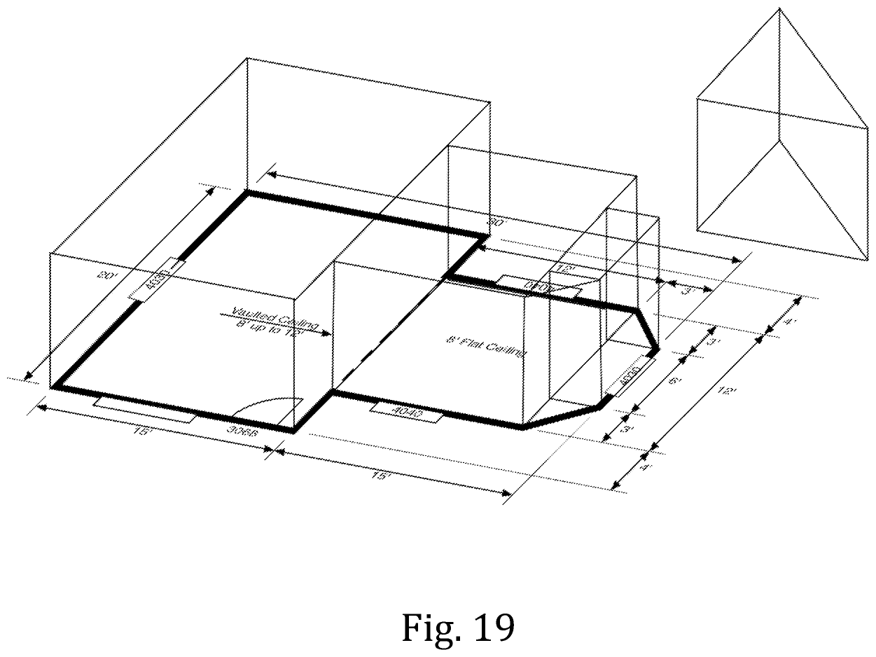

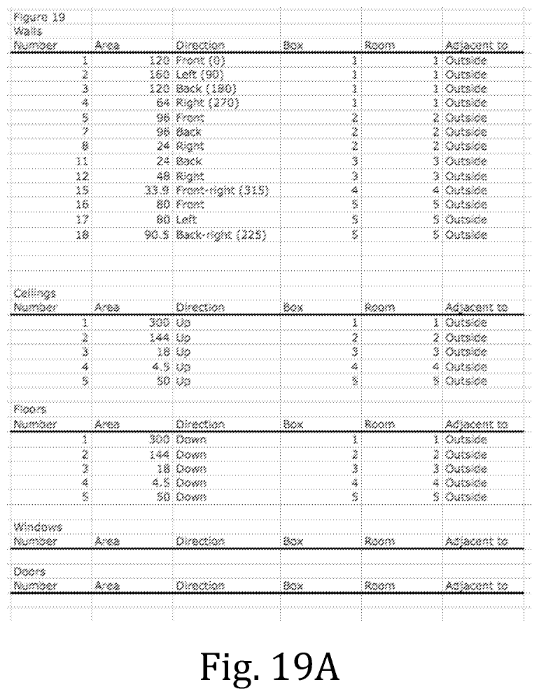

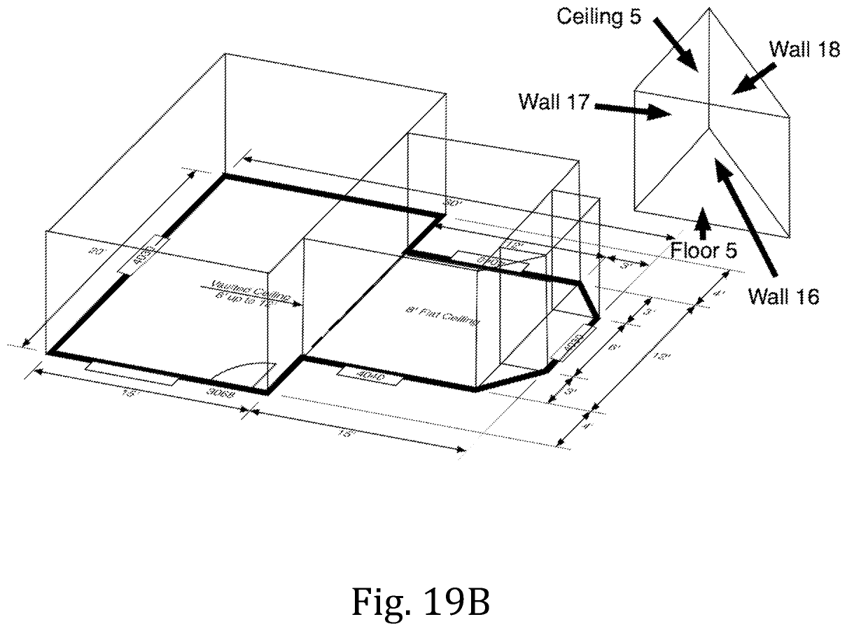

Next, the second scalable triangular prism must be rotated to align and coincide with the walls of the last open area or unfilled area of the small room by rotating the second scalable triangular prism around a vertical axis to align and coincide with the walls of the last open area or unfilled area of the small room. One method to accomplish this with the software is to select the whole second scalable triangular prism, using the mouse or track pad, and rotating the whole second scalable triangular prism to align and coincide with a corner of the open area or unfilled area of the small room, at which time the mouse or track pad is clicked or released to deselect the whole first scalable triangular prism to leave it at this new orientation in alignment with a corner of the formerly open area or unfilled area. This is depicted in FIG. 19.

FIG. 19A represents the real-time tabulation or matrix of exterior surface data of the three-dimensional model of the living space or interior space of a house or building depicted in FIG. 19, showing that the direction of wall number 16 changed to Front, the direction of wall number 17 changed to Left, and the direction of wall number 18 changed to Back-right.

Next, the second scalable triangular prism must be sized and exactly positioned to align and coincide with the walls of the last open area or unfilled area of the small room by re-sizing the length and the width of the scalable triangular prism and/or re-locating the entire scalable triangular prism to align and coincide with these walls.

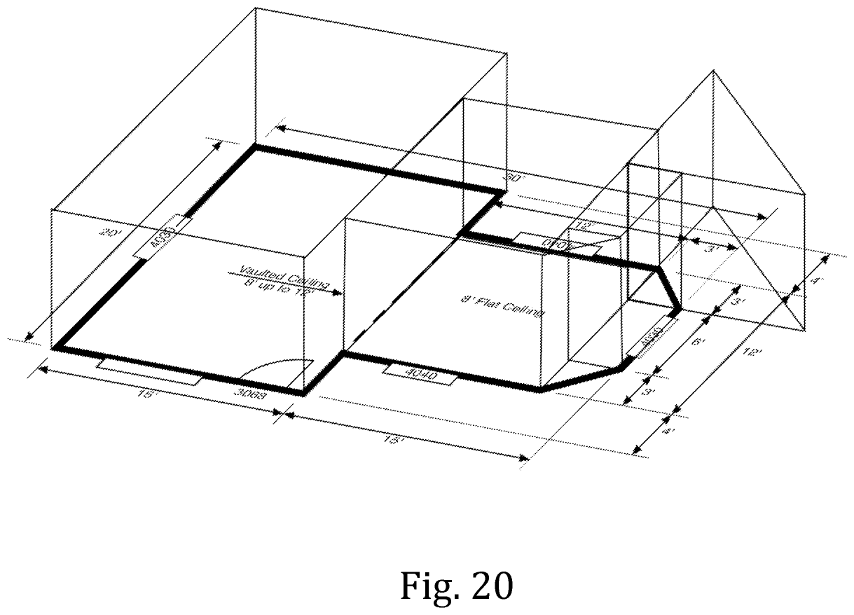

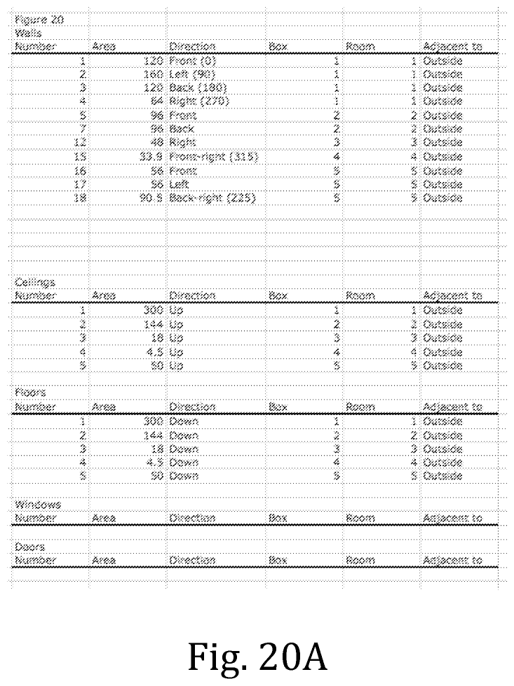

One method to accomplish this with the software is to select the whole second scalable triangular prism, using the mouse or track pad, and locating or relocating the whole second scalable triangular prism to align and coincide with a corner of the open area or unfilled area of the small room, at which time the mouse or track pad is clicked or released to deselect the whole first scalable triangular prism to leave it at this new location in alignment with a corner of the formerly open area or unfilled area. As stated, in best mode, there is a “collide and snap” mechanism or function in the software, where one scalable cuboid and/or scalable triangular prism will not pass through another, where the two walls of each scalable cuboid and/or scalable triangular prism collide with each other and then snap onto each other to effectuate an automatic alignment between the two colliding walls. This is depicted in FIG. 20.

Whenever placing scalable cuboids and/or scalable triangular prisms next to each other, they must be positioned or located to exactly align and coincide with each other, without any gaps there between.

FIG. 20A represents the real-time tabulation or matrix of exterior surface data of the three-dimensional model of the living space or interior space of a house or building depicted in FIG. 20, which shows that: wall numbers 1-4, 5, and 7 stayed the same; wall number 8 was deleted; wall number 11 was deleted; wall numbers 12 and 15 stayed the same; wall numbers 16 and 17 decreased in surface area from 80 to 56 square feet; wall 18 stayed the same; ceiling numbers 1-5 stayed the same; and floor numbers 1-5 stayed the same.

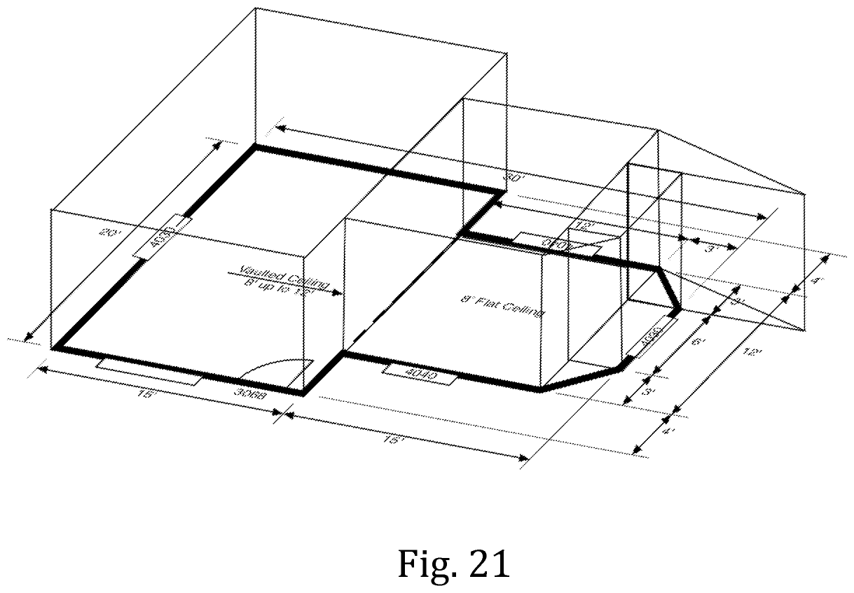

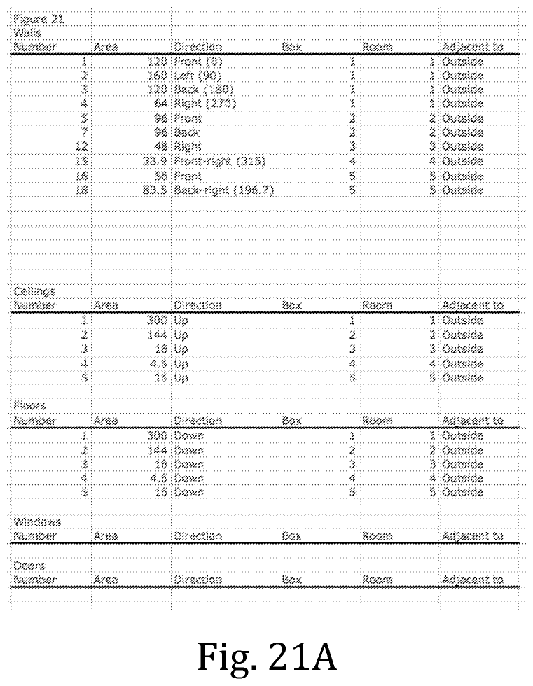

Next, the second scalable triangular prism must be sized and exactly positioned to align and coincide with all walls of the last open area or unfilled area of the small room by sizing or re-sizing the length and the width of the scalable triangular prism. This is accomplished by selecting one of the edges or corners of the second scalable triangular prism not yet in alignment with the last open area or unfilled area of the small room is selected by the cursor, using the mouse or track pad, and stretching or moving it to exactly align with and coincide with the corresponding edge or corner of the last open area or unfilled area of the small room, at which time the mouse or track pad is clicked or released to leave the edge or corner at this new location, thereby sizing or re-sizing the second scalable triangular prism in one dimension, which would be the length or width dimension of the room. The action of sizing or re-sizing the first scalable triangular prism in one dimension is depicted in FIG. 21.

FIG. 21A represents the real-time tabulation or matrix of exterior surface data of the three-dimensional model of the living space or interior space of a house or building depicted in FIG. 21, which shows that: wall numbers 1-5, 7, 12, 15, and 16 stayed the same; wall number 17 was deleted; wall number 18 decreased in surface area from 90.5 to 83.5 square feet; ceiling numbers 1-4 stayed the same; floor numbers 1-4 stayed the same; ceiling number 5 decreased in surface area from 50 to 15 square feet; and floor number 5 decreased in surface area from 50 to 15 square feet.

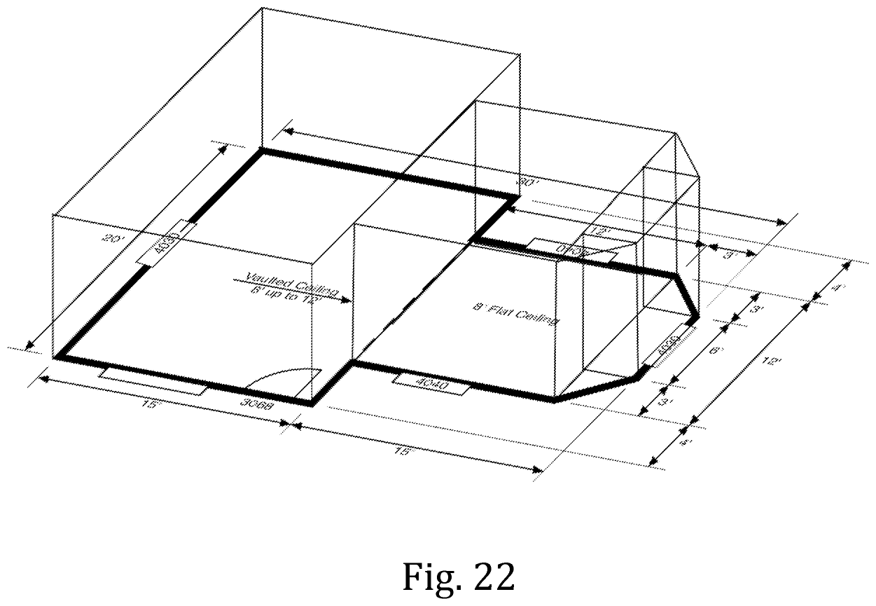

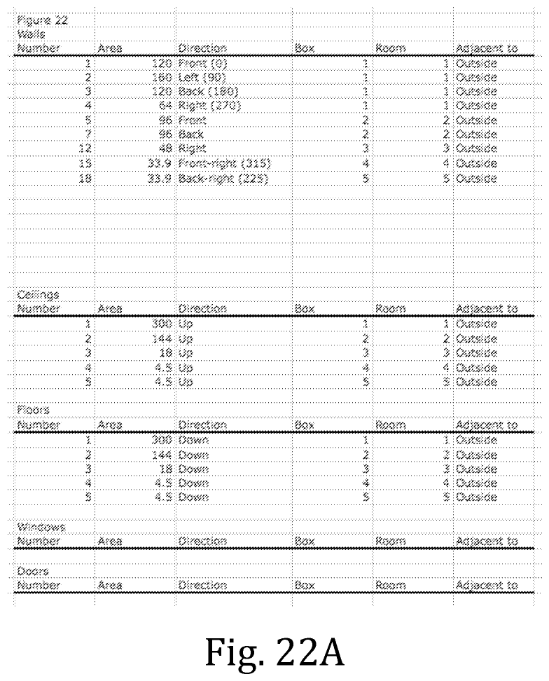

Next, one of the remaining edges or corners of the first scalable triangular prism not yet in alignment with the open area or unfilled area of the small room is selected by the cursor, using the mouse or track pad, and stretched or moved to exactly align with and coincide with the corresponding edge or corner of the open area or unfilled area of the small room, at which time the mouse or track pad is clicked or released to leave the edge or corner at this new location, thereby sizing or re-sizing the first scalable triangular prism in last dimension, which would be the length or width of the room. The action of sizing or re-sizing the first scalable triangular prism in the last dimension is depicted in FIG. 22.

FIG. 22A represents the real-time tabulation or matrix of exterior surface data of the three-dimensional model of the living space or interior space of a house or building depicted in FIG. 22, which shows that: wall numbers 1-5, 7, 12, and 15 stayed the same; wall number 16 was deleted; wall number 18 decreased in surface area from 83.5 to 33.9 square feet; ceiling numbers 1-4 stayed the same; floor numbers 1-4 stayed the same; ceiling number 5 decreased in surface area from 15 to 4.5 square feet; and floor number 5 decreased in surface area from 15 to 4.5 square feet.

After the entire living space or interior space of every room on a floor or floor plan is filled with scalable cuboids and/or scalable triangular prisms, all contiguous scalable cuboids and/or scalable triangular prisms in a particular room are grouped together to create one large room. The software has a mechanism or function to group or add two or more contiguous boxes or box numbers together in order to create one larger room made up of the plurality of different boxes or box numbers. After the entire the living space or interior space on a floor or floor plan is filled with scalable cuboids and/or scalable triangular prisms, this mechanism or function is performed to equalize the number of rooms in the floor plan with the number of rooms in the real-time tabulation or matrix of exterior surface data of the three-dimensional model of the living space or interior space of a house or building.

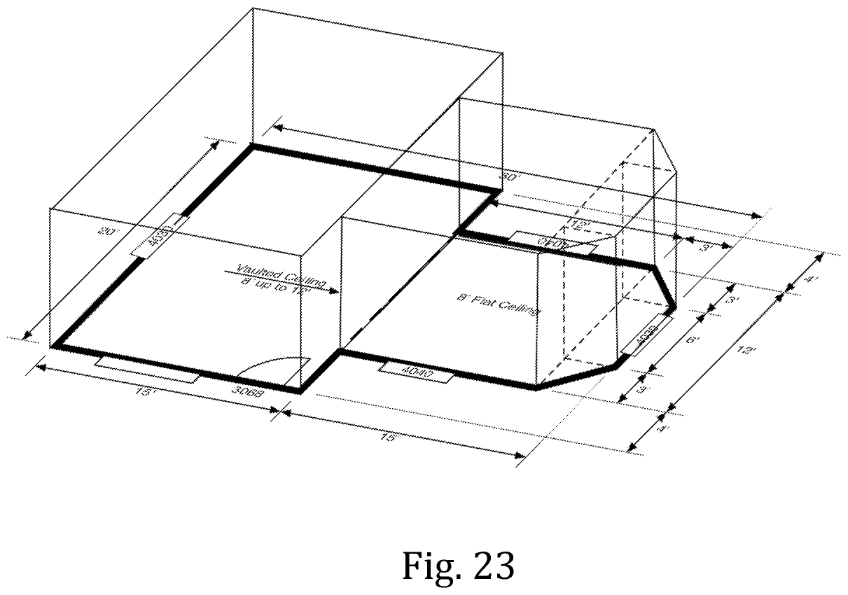

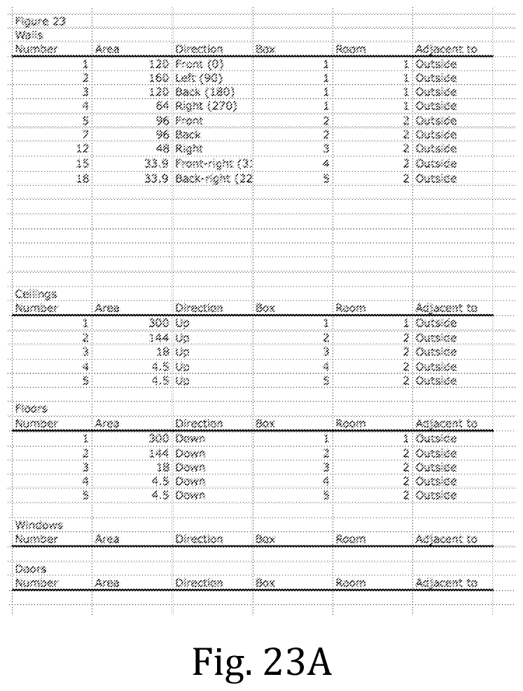

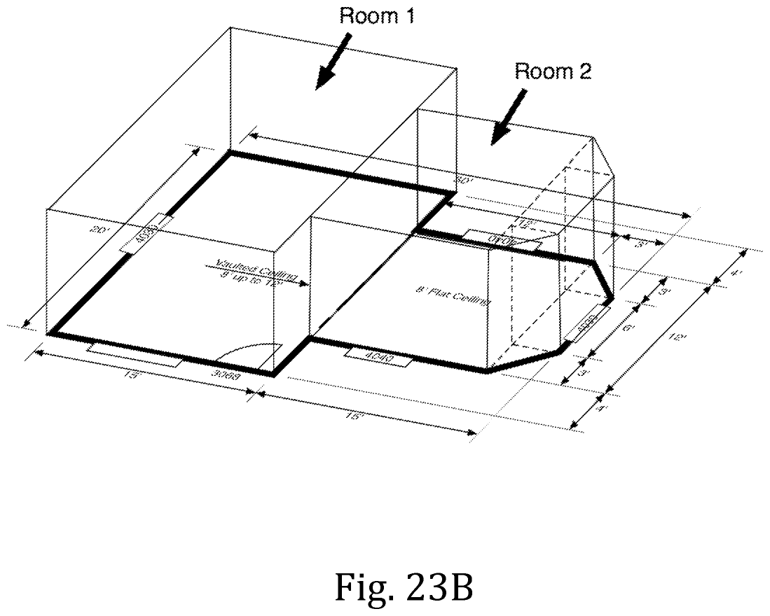

This mechanism or function is demonstrated in FIG. 23 where box numbers 2, 3, 4, and 5 are grouped together to form one room. Prior to this, there are five rooms, where each room is a particular scalable cuboid or scalable triangular prism. After box numbers 2, 3, 4, and 5 are joined together at the seams depicted in dashed lines in FIG. 23, box numbers 2, 3, 4, and 5 are joined together to form a single room, which is designated as room number 2. Now there are a total of two rooms: room 1 that is box number 1 and room 2 that is box numbers 2-5. Note that from this point forward, the software depicts all joined seams in dashed lines.

FIG. 23A represents the real-time tabulation or matrix of exterior surface data of the three-dimensional model of the living space or interior space of a house or building depicted in FIG. 23, which shows that: wall numbers 1-5, and 7 stayed the same; wall numbers 12, 15, and 18 were re-assigned to room number 2; ceiling numbers 1 and 2 stayed the same; floor numbers 1 and 2 stayed the same; ceiling numbers 3-5 were re-assigned to room number 2; and floor numbers 3-5 were re-assigned to room number 2. Thus, room number 2, which is the small room on the example floor plan, is made up of: two scalable cuboids that are box numbers 2 and 3; and two scalable triangular prisms that are box numbers 4 and 5. Note that the box numbers of all surfaces remain the same, where the box number is tied to the original scalable cuboid or scalable triangular prism used to create the “box”, noting that a triangular prism is still called a box even though it is not really box shaped. After this process, the number of rooms in the real-time tabulation or matrix of exterior surface data of the three-dimensional model of the living space or interior space of a house or building should match the number of rooms on the actual floor plan.

After all the rooms of the floor or floor plan are filled with scalable cuboids and/or scalable triangular prisms, next, any ceiling space above all of the rooms on a floor or floor plan must also be filled with one or more scalable cuboids and/or one or more scalable triangular prisms. Each scalable cuboid and/or scalable triangular prism used to fill in the ceiling space is called a ceiling box. A ceiling box could be a scalable cuboid or a scalable triangular prism. As stated above, each scalable cuboid is created in a default size that may be adjusted. Each scalable cuboid is created with four wall surfaces, a ceiling surface, four corners, and 12 edges. Wall surfaces are vertical. The ceiling surface is horizontal. There is no floor in a ceiling box because this is open space in the floor plan. As stated above, each scalable triangular prism is created in a default size that may be adjusted. Each scalable triangular prism is created with three wall surfaces, a ceiling surface, six corners, and nine edges. Wall surfaces are vertical. The ceiling surface of a ceiling box scalable triangular prism is not horizontal but is slanted or angled to accommodate a vaulted ceiling on the floor plan. There is no floor in a ceiling box because this is open space in the floor plan.

In the example floor plan, only one ceiling box is required, which is a scalable triangular prism. Typically, a house or building has a pitched roof or an A-frame roof; with this type of roof, two scalable triangular prisms would be used to fill the entire ceiling space above all rooms on a floor or floor plan. In the example floor plan, only one scalable triangular prism is required to fill the ceiling space above all rooms.

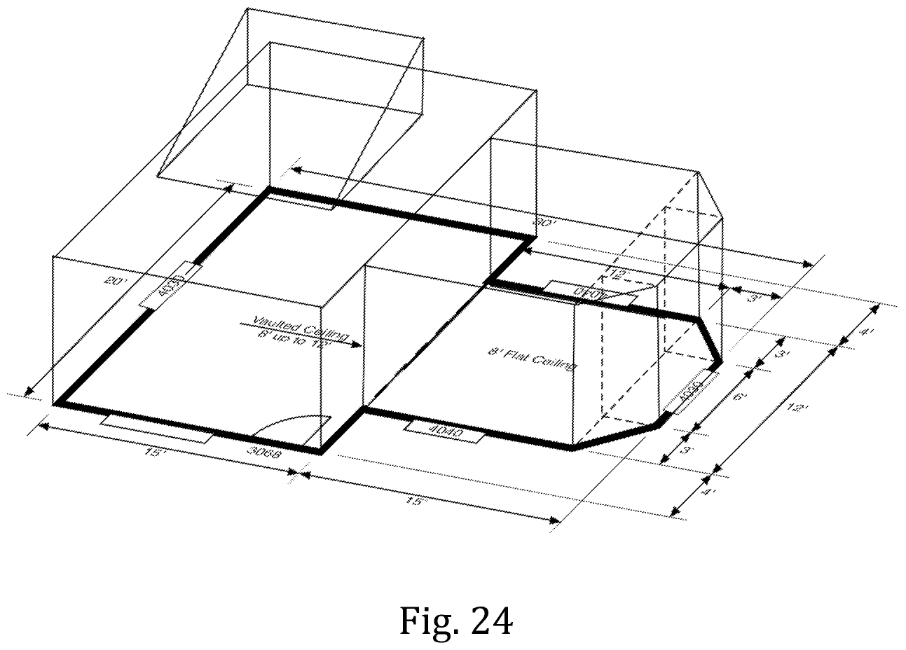

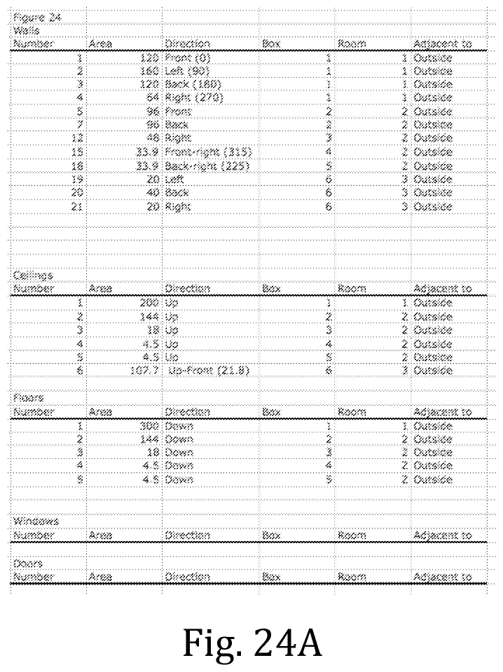

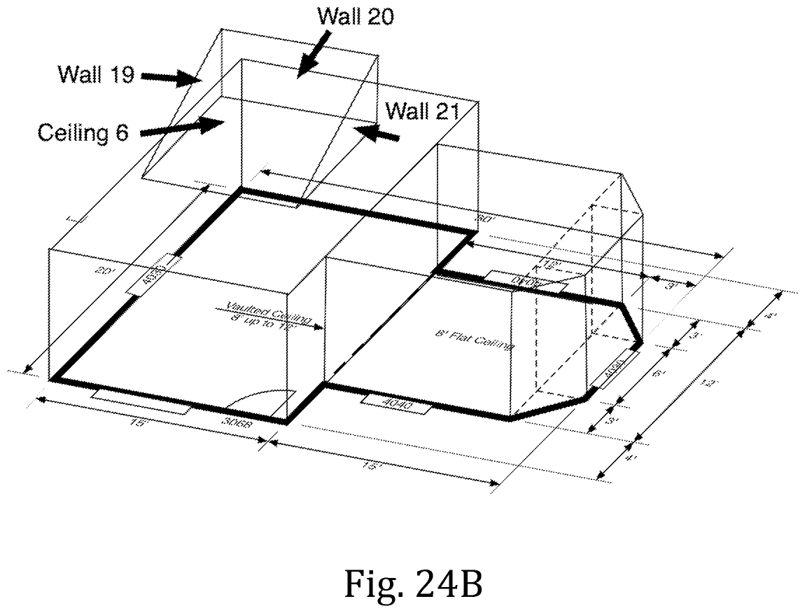

Next, the first ceiling box is created and positioned on the example floor plan. The first ceiling box is a scalable triangular prism. The first ceiling box is box number 6. One method to create a ceiling box in the software is to: enter a command in the software through the keyboard, mouse, or track pad, and position the cursor over the ceiling of the large room, and press or click the mouse, or track pad to create a scalable triangular prism on the large room. Each scalable triangular prism has three wall surfaces, a ceiling surface, a floor surface, six corners, and nine edges. Wall surfaces are vertical. Ceiling surface is angled or slanted. Floor surface is horizontal. The first ceiling box is depicted in FIG. 24 as it would appear on the computer screen.

The creation of the first ceiling box changes the real-time tabulation or matrix of exterior surface data by adding three walls designated as wall numbers 19-21, consecutively. The surface area of wall numbers 19 and 21 each have a surface area of 20 square feet. Wall number 20 has a surface area of 40 square feet. The direction of the three walls is indicated as Left, Back, and Right, consecutively. The box number of each of the three walls is indicated as 6. The room number of each of the three walls is indicated as 3. The Adjacent to field of each of the three walls is designated as Outside.

The creation of the first ceiling box changes the real-time tabulation or matrix of exterior surface data by adding a ceiling designated as ceiling number 6. The surface area of ceiling number 6 is indicated as 107.7 square feet. The direction of ceiling number 6 is indicated as Up-Front. The box number of ceiling number 6 is indicated as 6. The room number of ceiling number 6 is indicated as 3. The Adjacent to field of ceiling number 4 is designated as Outside.

The creation of first ceiling box does not add a floor to the real-time tabulation or matrix of exterior surface data because the floor of the first ceiling box is coincident with ceiling number 1 of room number 1. The software of this invention recognizes these coincidences of ceilings and floors of different scalable cuboids and/or scalable triangular prisms, and reacts by rendering the coincident sections of the ceilings and floors as non-existent and renders the coincident sections of ceilings and floors as open space in the interior of the three dimensional model of the living space or interior space of a house or building. Thus, floor number 6 was never created and the overlap portion the non-existent floor number 6 of ceiling number 1 is removed from ceiling number 1 in the real-time tabulation or matrix of exterior surface data by the square.

FIG. 24A represents the real-time tabulation or matrix of exterior surface data of the three-dimensional model of the living space or interior space of a house or building depicted in FIG. 24, showing that: three more walls were created with wall numbers 19-21, with wall numbers 19 and 21 each having a surface area of 20 square feet and wall number 20 having a surface area of 40 square feet; each new wall belonging to box number 6 and room number 3; one more ceiling was created with ceiling number 6, having a surface area of 107.7 square feet, belonging to box number 6 and room number 3; and ceiling number 1 decreased in surface area from 300 to 200 square feet.

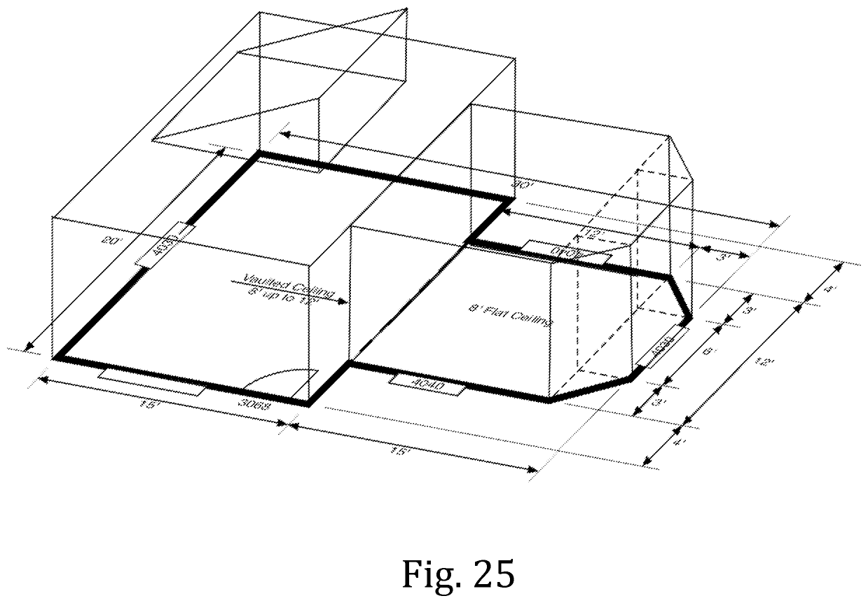

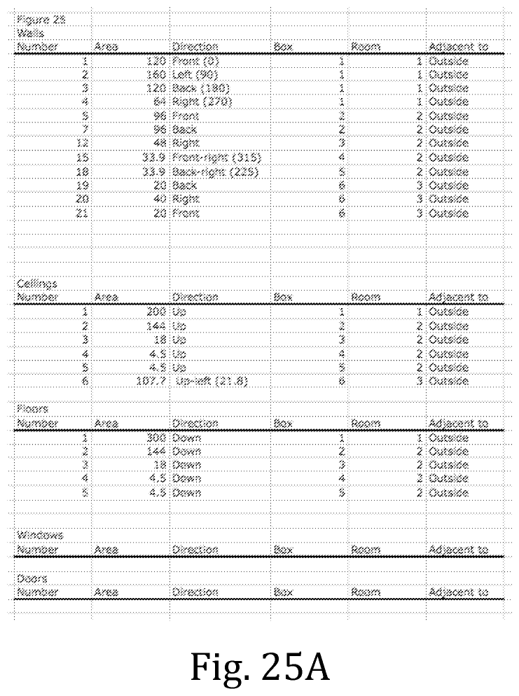

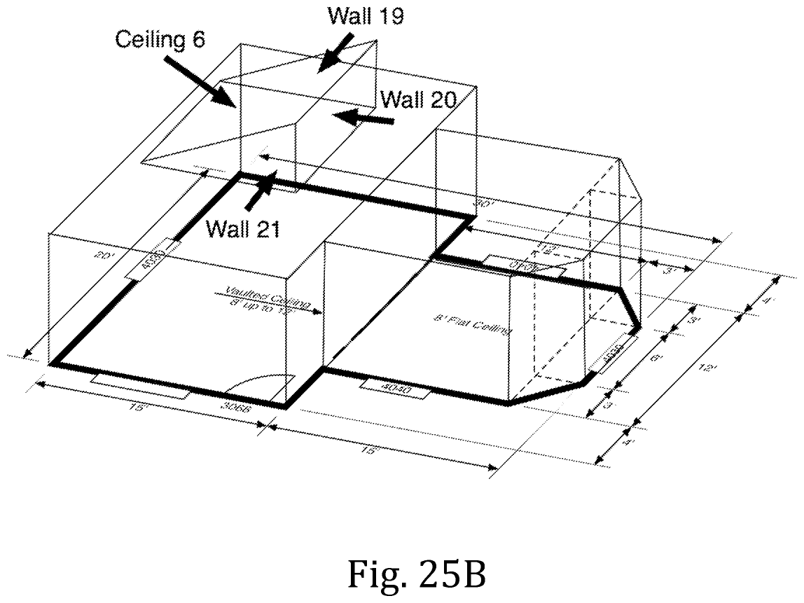

Next, the first ceiling box must be rotated to align and coincide with the ceiling specified on the floor plan by rotating the first ceiling box around a vertical axis to align to coincide with the walls and ceiling of the target open area or unfilled area. One method to accomplish this with the software is to select the whole second scalable triangular prism, using the mouse or track pad, and rotating the whole second scalable triangular prism to align and coincide with the ceiling specified on the floor plan, at which time the mouse or track pad is clicked or released to deselect the whole scalable triangular prism to leave it at this new orientation and alignment. This is depicted in FIG. 25.

FIG. 25A represents the real-time tabulation or matrix of exterior surface data of the three-dimensional model of the living space or interior space of a house or building depicted in FIG. 25, showing that the direction of wall number 19 changed to Back, the direction of wall number 20 changed to Right, the direction of wall number 21 changed to Front, and the direction of ceiling number 6 changed to Up-left.

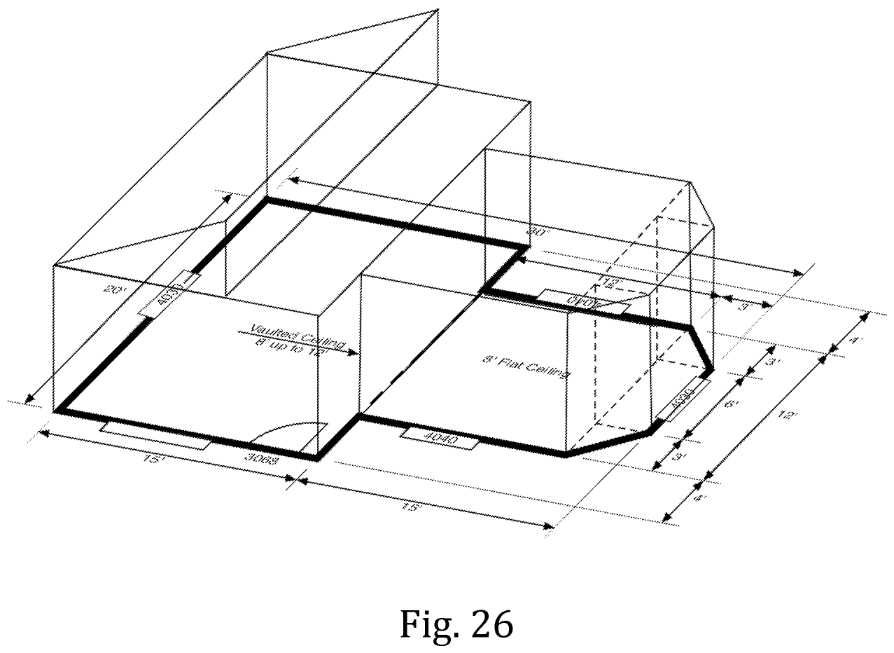

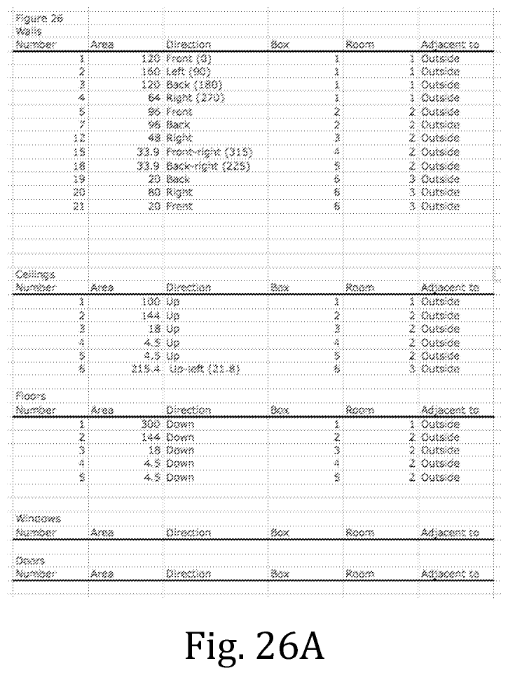

Next, the first ceiling box must be sized and exactly positioned to align and coincide with the walls of floor plan by re-sizing the length and the width of the scalable triangular prism and/or re-locating the entire scalable triangular prism to align and coincide with these walls. One method to accomplish this with the software is to select one of the edges or corners of the scalable cuboid not yet in alignment with the floor plan, using the mouse or track pad, and stretching or moving it to exactly align with and coincide with the corresponding edge or corner of the room being filled, at which time the mouse or track pad is clicked or released to leave the edge or corner at this new location, thereby sizing or re-sizing the scalable cuboid in one dimension, which would be the length or width dimension of the room. Note that the height dimension of the ceiling was already set by entering the ceiling height or plate height as stated above. The action of sizing or re-sizing this scalable cuboid in one dimension is depicted in FIG. 26.

FIG. 26A represents the real-time tabulation or matrix of exterior surface data of the new size, showing that wall numbers 19 and 21 stayed the same at 20 square feet, wall number 20 increased in surface area from 40 to 80 square feet, ceiling number 1 decreased in surface are from 200 to 100 square feet; and ceiling number 6 increased in surface area from 107.7 to 215.4 square feet, where all other data remained the same from FIG. 25A.

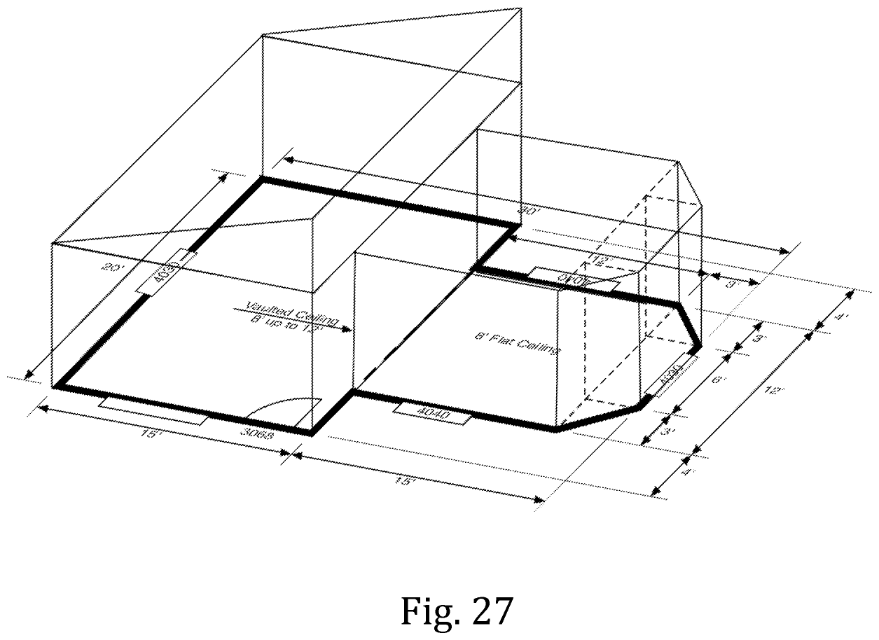

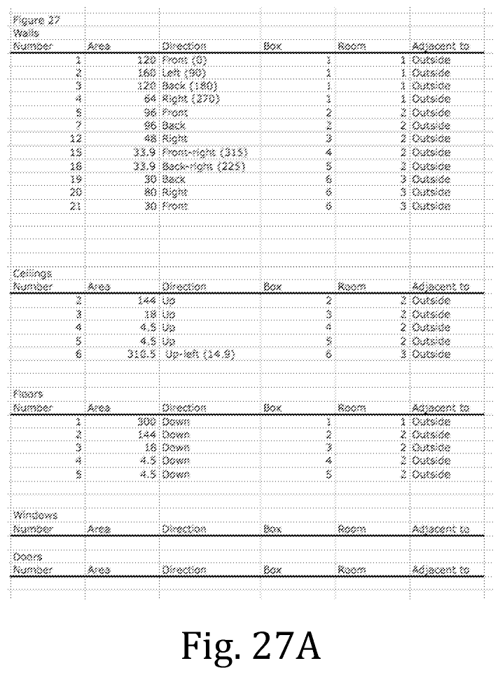

Next, one of the remaining edges or corners of the scalable triangular prism not yet in alignment with the open area or unfilled area of the room is selected by the cursor, using the mouse or track pad, and stretched or moved to exactly align with and coincide with the corresponding edge or corner of the open area or unfilled area of the room, at which time the mouse or track pad is clicked or released to leave the edge or corner at this new location, thereby sizing or re-sizing the scalable triangular prism in last dimension, which would be the length or width of the room. The action of sizing or re-sizing the first scalable triangular prism in the last dimension is depicted in FIG. 27.

FIG. 27A represents the real-time tabulation or matrix of exterior surface data of the three-dimensional model of the living space or interior space of a house or building depicted in FIG. 17, which shows that: wall numbers 19 and 21 increased in surface area from 20 to 30 square feet; wall number 20 stay the same; ceiling number 1 was deleted; and ceiling number 6 increased in surface area from 215.4 to 310.5 square feet, where all other data remained the same from FIG. 26A

After the entire the ceiling space on a floor or floor plan is filled with scalable cuboids and/or scalable triangular prisms, all contiguous scalable cuboids and/or scalable triangular prisms in a room are grouped together to create one large room. As stated, all contiguous scalable cuboids and/or scalable triangular prisms inside as room have already been grouped together to create one large room as depicted in FIG. 23. In this step, we are grouping together all contiguous scalable cuboids and/or scalable triangular prisms of each room in the newly create ceiling space or ceiling blocks to create one larger room. The software has a mechanism or function to group or add two or more contiguous boxes or box numbers together in order to create one larger room made up of the plurality of different boxes or box numbers. After the entire the living space or interior space on a floor or floor plan is filled with scalable cuboids and/or scalable triangular prisms, this mechanism or function is performed to equalize the number of rooms in the floor plan with the number of rooms in the real-time tabulation or matrix of exterior surface data of the three-dimensional model of the living space or interior space of a house or building.

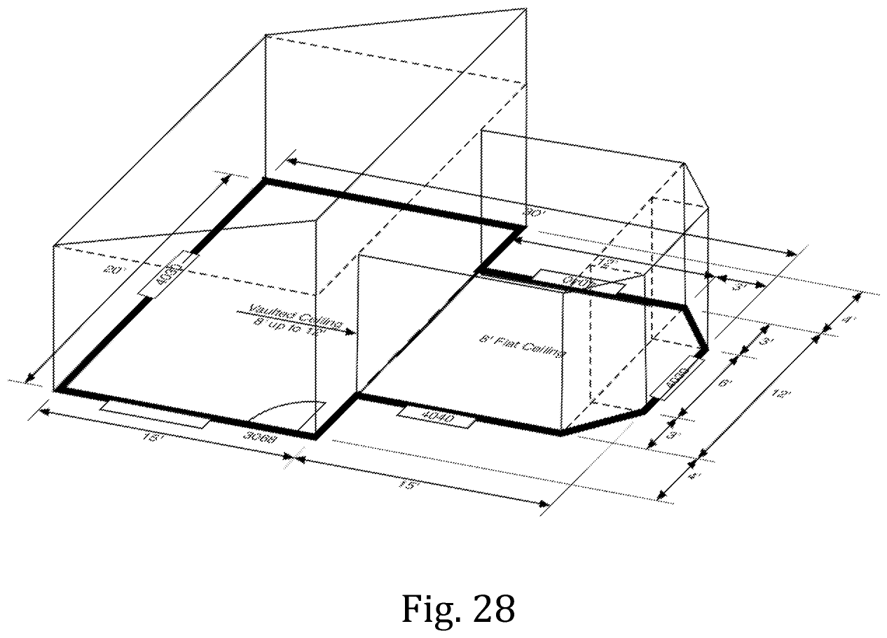

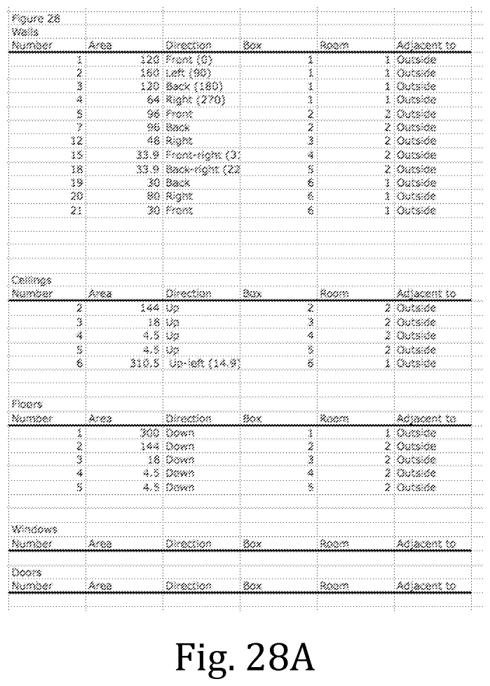

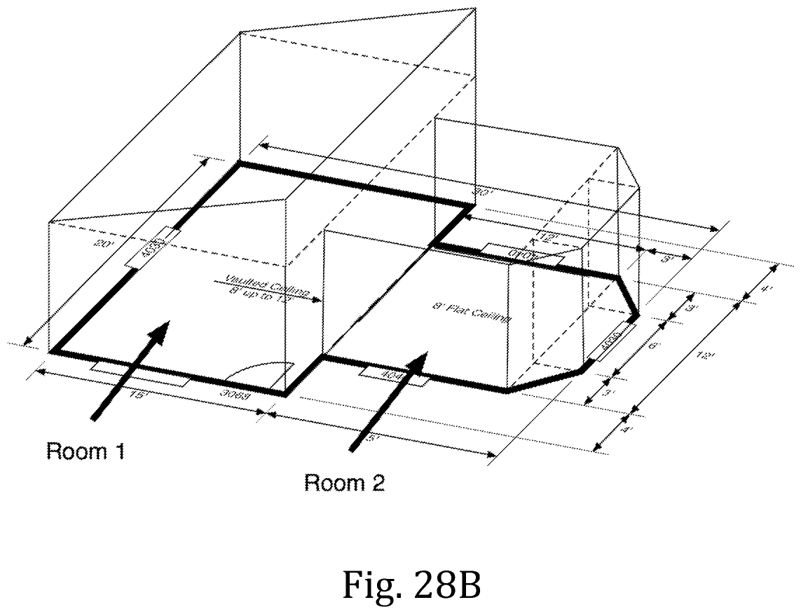

This mechanism or function is demonstrated in FIG. 28 where box numbers 1 and 6 are grouped together to form one room. Prior to this, in FIG. 27A, there are three rooms. After box numbers 1 and 6 are joined together at the seams depicted in dashed lines in FIG. 28, box numbers 1 and 5 are joined together to form a single room, which is designated as room number 1. Now there are a total of two rooms: room 1 that is box numbers 1 and 6; and room 2 that is box numbers 2-5. Note that from this point forward, the software depicts all joined seams in dashed lines.

FIG. 28A represents the real-time tabulation or matrix of exterior surface data of the three-dimensional model of the living space or interior space of a house or building depicted in FIG. 28, which shows that: wall numbers 1-5, 7, 12, 15, and 18 stayed the same; wall numbers 19-20 were re-assigned to room number 1; ceiling numbers 2-5 stayed the same; ceiling number 6 was re-assigned to room number 1; and floor numbers 1-5 stayed the same. Thus, room number 1, which is the large room on the example floor plan, is made up of: one scalable cuboid that is box number 1 and one scalable triangular prism that is box number 6. Note that the box numbers of all surfaces remain the same, where the box number is tied to the original scalable cuboid or scalable triangular prism used to create the “box”, noting that a triangular prism is still called a box even though it is not really box shaped. After this process, the number of rooms in the real-time tabulation or matrix of exterior surface data of the three-dimensional model of the living space or interior space of a house or building should match the number of rooms on the actual floor plan.

Next, all windows are added to the three dimensional model of the living space or interior space of a house or building from a floor-plan drawing of the house or building as specified on the floor plan. One method to do this with the software is to: enter a command in the software through the keyboard, mouse, or track pad, enter the designated width and height of the window as specified by the floor plan, and position the cursor over the designated wall or wall number, and press or click the mouse, or track pad to create the window as specified in the floor plan. Each window is created with a window number, a surface area, a direction facing field, a box number, a room number, and an adjacent to field. Window numbers are created sequentially. The surface area of each window is specified when the window is created. The direction facing field of each window matches that of the wall number that the window is being installed in. The box number of each window matches that of the wall number that the window is being installed in. The room number of each window matches that of the wall number that the window is being installed in. Note that the exact position of the window on the wall does not really matter because the thermal effects of the window are essentially irrelevant to the exact position of the window on a particular wall. All windows specified on the floor plan would be created this way.

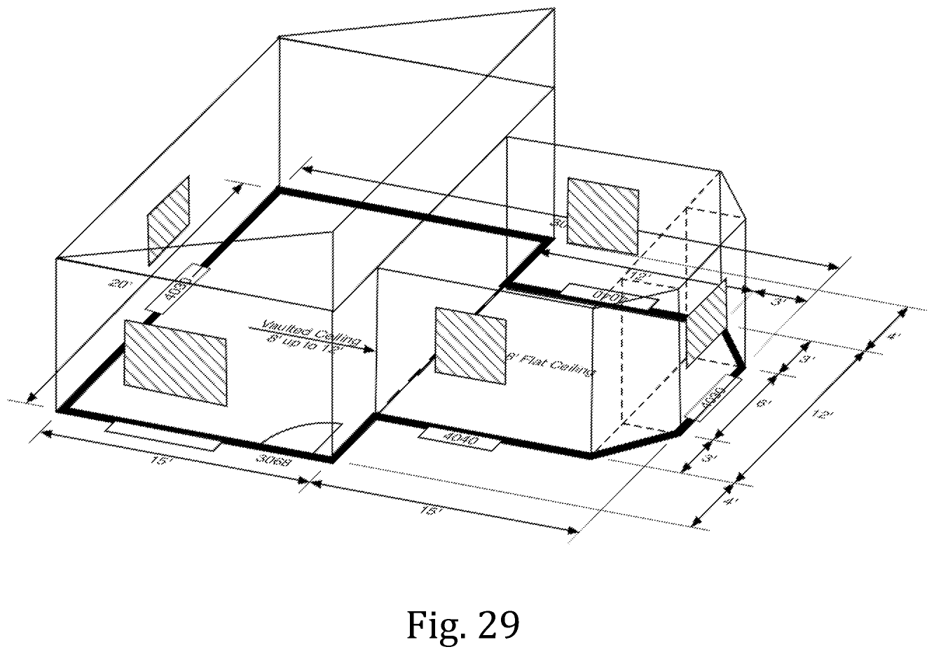

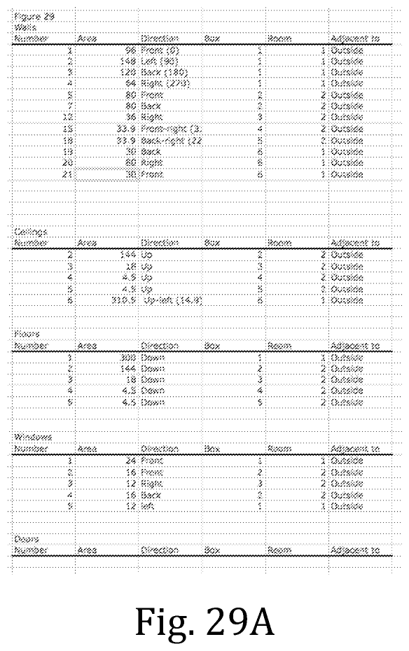

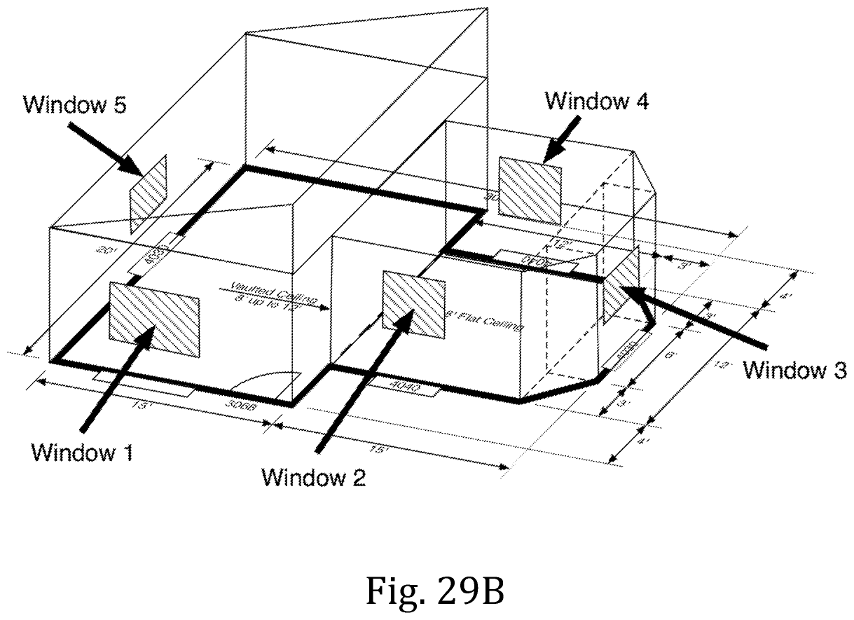

The example floor plan calls for five windows. FIG. 29 depicts the addition of these five windows. FIG. 29 depicts that windows have been added to wall numbers 1, 2, 5, 7, and 12. The surface area of each of these walls has been reduced by the surface area of the particular window installed into each wall. The surface area of window number 1 is indicated as 24 square feet. The direction of window number 1 is indicated as Front. The box number of window number 1 is indicated as 1. The room number of window number 1 is indicated as 1. The Adjacent to field of window number 1 is designated as Outside. The surface area of window number 2 is indicated as 16 square feet. The direction of window number 2 is indicated as Front. The box number of window number 2 is indicated as 2. The room number of window number 2 is indicated as 2. The Adjacent to field of window number 2 is designated as Outside. The surface area of window number 3 is indicated as 12 square feet. The direction of window number 3 is indicated as Right. The box number of window number 2 is indicated as 3. The room number of window number 3 is indicated as 2. The Adjacent to field of window number 3 is designated as Outside. The surface area of window number 4 is indicated as 16 square feet. The direction of window number 4 is indicated as Back. The box number of window number 4 is indicated as 2. The room number of window number 4 is indicated as 2. The Adjacent to field of window number 4 is designated as Outside. The surface area of window number 5 is indicated as 12 square feet. The direction of window number 5 is indicated as Left. The box number window number 5 is indicated as 1. The room number of window number 5 is indicated as 1. The Adjacent to field of window number 5 is designated as Outside.

FIG. 29A represents the real-time tabulation or matrix of exterior surface data of the three-dimensional model of the living space or interior space of a house or building depicted in FIG. 29, which shows that: wall number 1 decreased in surface area from 120 to 96 square feet; wall number 2 decreased in surface area from 160 to 148 square feet; wall numbers 3 and 4 stayed the same; wall number 5 decreased in surface area from 96 to 80 square feet; wall number 7 decreased in surface area from 96 to 80 square feet; wall number 12 decreased in surface area from 48 to 36 square feet; wall numbers 15, 18, and 19-21 stayed the same; ceiling numbers 2-6 stayed the same; floor numbers 1-5 stayed the same; window number 1 was created with a surface area of 24 square feet; window number 2 was created with a surface area of 16 square feet; window number 3 was created with a surface area of 12 square feet; window number 4 was created with a surface area of 16 square feet; and window number 5 was created with a surface area of 12 square feet.

Next, all doors are added to the three dimensional model of the living space or interior space of a house or building from a floor-plan drawing of the house or building as specified on the floor plan. One method to do this with the software is to: enter a command in the software through the keyboard, mouse, or track pad, enter the designated width and height of the door as specified by the floor plan, and position the cursor over the designated wall or wall number, and press or click the mouse, or track pad to create the door as specified in the floor plan. Each door is created with a door number, a surface area, a direction facing field, a box number, a room number, and an adjacent to field. Door numbers are created sequentially. The surface area of each door is specified when the door is created. The direction facing field of each door matches that of the wall number that the door is being installed in. The box number of each door matches that of the wall number that the door is being installed in. The room number of each window matches that of the wall number that the door is being installed in. Note that the exact position of a door on the wall does not really matter because the thermal effects of the door are essentially irrelevant to the exact position of the door on the wall. All doors specified on the floor plan would be created this way.

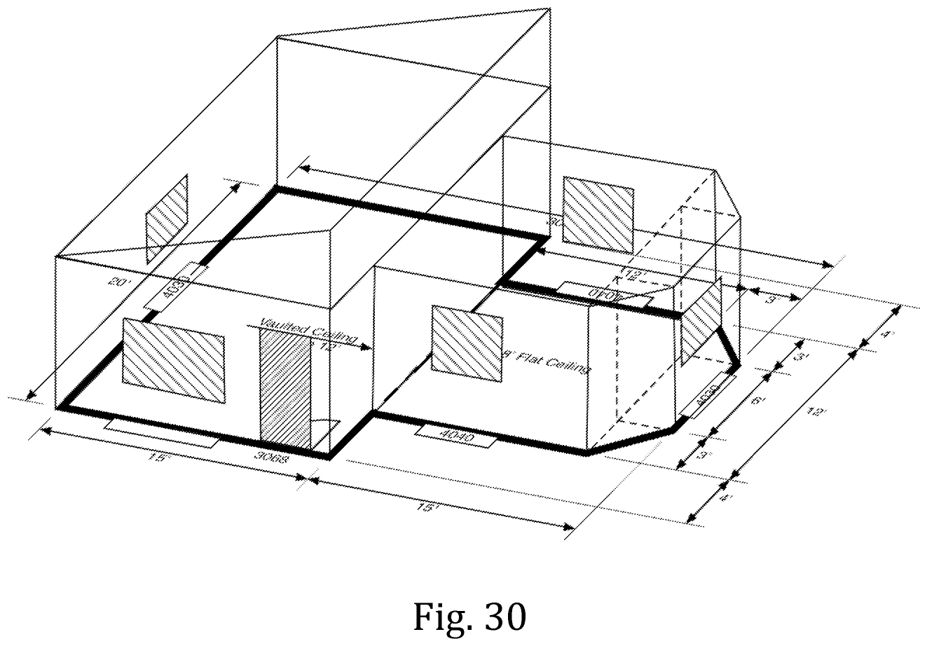

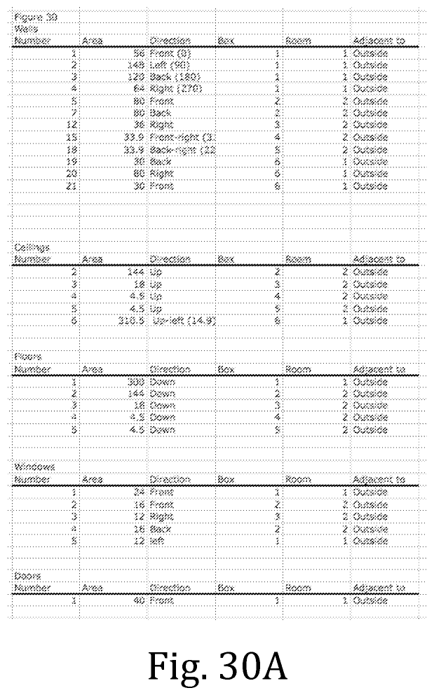

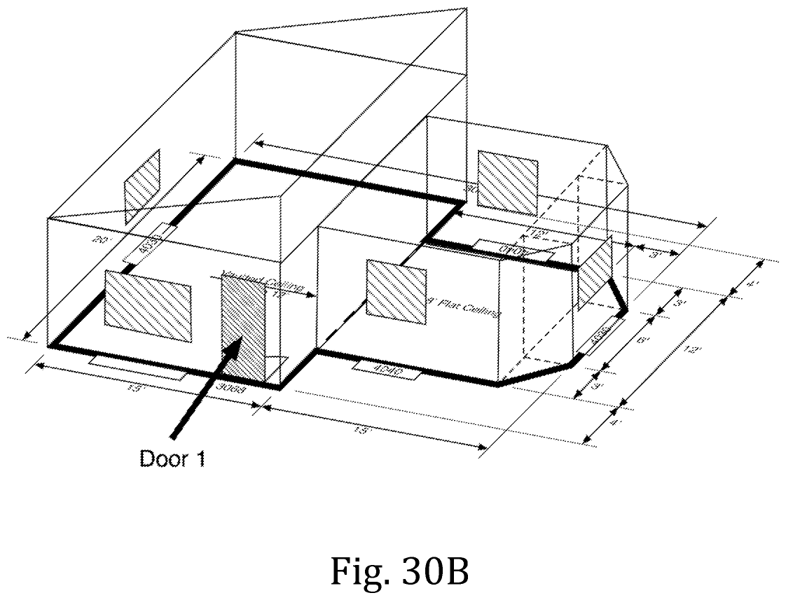

The example floor plan calls for one door. FIG. 30 depicts the addition of this door. FIG. 30 depicts that a door has been added to wall number 1. The surface area of wall number 1 has been reduced by the surface area of the particular door installed therein. The surface area of door number 1 is indicated as 40 square feet. The direction of door number 1 is indicated as Front. The box number of door number 1 is indicated as 1. The room number of door number 1 is indicated as 1. The Adjacent to field of window number 1 is designated as Outside.

FIG. 30A represents the real-time tabulation or matrix of exterior surface data of the three-dimensional model of the living space or interior space of a house or building depicted in FIG. 30, which shows that: wall number 1 decreased in surface area from 96 to 56 square feet; wall numbers 2-5, 7, 12, 15, 18, and 19-21 stayed the same; ceiling numbers 2-6 stayed the same; floor numbers 1-5 stayed the same; and door number 1 was created with a surface area of 40 square feet.

At this point, the three-dimensional model of the living space or interior space of a house or building is completed. Note that there is exact alignment between all interior walls of each scalable cuboid and scalable triangular prism, wherein all interior walls are coincident with the contiguous wall of their neighboring scalable cuboid or scalable triangular prism, so that there are no gaps or overlap between any scalable cuboids and/or scalable triangular prisms. All exterior walls, ceilings, and floors of each scalable cuboid and scalable triangular prism are coincident with the contiguous surface of the wall, ceiling, or floor of the floor plan, so that there are no gaps or overlap between any scalable cuboids and/or scalable triangular prisms and the floor plan. If any such gaps or overlap exist, the real-time tabulation or matrix of exterior surface data of the three-dimensional model of the living space or interior space of a house or building will have inaccurate information.

The completed real-time tabulation or matrix of exterior surface data of the three-dimensional model of the living space or interior space of a house or building is depicted in FIG. 30A. This real-time tabulation or matrix of exterior surface data of the three-dimensional model of the living space or interior space of a house or building would then entered into another software package or subroutine to determine the optimum size of HVAC system and/or the optimum size and structure of air ductwork or ducting and/or other energy modeling of the living space or interior space of a house or building.

The completed real-time tabulation or matrix of exterior surface data of the three-dimensional model of the living space or interior space of a house or building is the complete data set for all exterior surfaces of the three-dimensional model of the living space or interior space of a house or building. The completed real-time tabulation or matrix of exterior surface data of the three-dimensional model of the living space or interior space of a house or building includes twelve walls or wall segments—wall numbers 1-5, 7, 12, 15, and 18-21. Each of the twelve walls or wall segments is an exterior wall of the three-dimensional model of the living space or interior space of a house or building. There is a surface area noted for each of the twelve walls or wall segments. Of course, all window and all door surface areas have been subtracted from the wall surface area tabulations. The completed real-time tabulation or matrix of exterior surface data of the three-dimensional model of the living space or interior space of a house or building includes five ceilings or ceiling segments—ceiling numbers 2-6. Each of the five ceilings or ceiling segments is a ceiling of the three-dimensional model of the living space or interior space of a house or building. There is a surface area noted for each of the five ceilings or ceiling segments. The completed real-time tabulation or matrix of exterior surface data of the three-dimensional model of the living space or interior space of a house or building includes five floors or floor segments—ceiling numbers 2-6. Each of the five floors or floor segments is floor of the three-dimensional model of the living space or interior space of a house or building. There is a surface area noted for each of the five floors or floor segments. The completed real-time tabulation or matrix of exterior surface data of the three-dimensional model of the living space or interior space of a house or building includes five windows or widow segments—window numbers 1-5. Each of the five windows or window segments is a window in the exterior of the three-dimensional model of the living space or interior space of a house or building. There is a surface area noted for each of the five windows or window segments. The completed real-time tabulation or matrix of exterior surface data of the three-dimensional model of the living space or interior space of a house or building includes one door or door segment—door number 1. Each door or door segment is a door in the exterior of the three-dimensional model of the living space or interior space of a house or building. There is a surface area noted for each of the doors or door segments. This data set is entered into another software package or subroutine to determine the optimum size of HVAC system and/or the optimum size and structure of air ductwork or ducting and/or other energy modeling of the living space or interior space of a house or building.

What is claimed is:

1. The process for constructing a three dimensional model of the living space or interior space of a house or building from a floor-plan drawing of the house or building, for use in sizing HVAC systems, sizing air ducting systems, or other energy modeling for the house or building, comprising the steps of:
obtaining a computer with: a keyboard, a screen or monitor, and a mouse or track pad used to direct a cursor on said screen or monitor;
loading or installing a software on said computer;
obtaining a digital file of a floor plan drawing of the living space or interior space of a house or building that shows a scaled two-dimensional depiction of all walls, all floors, all doors, and all windows;
uploading or importing said digital file into said software on said computer;
entering the wall height specified on said floor plan into said software on said computer;
entering the ceiling height or plate height specified on said floor plan into said software on said computer;
adding one or more scalable cuboids and/or one or more scalable triangular prisms to fill the entire living space or interior space of a house or building without any gaps or overlap between each of said one or more scalable cuboids and/or said one or more scalable triangular prisms to created said three-dimensional model of the living space or interior space specified on said floor plan; wherein, each said one or more scalable cuboids is a cuboid or hollow cube shaped member that is created in said software and depicted on said screen as an overlay on said floor plan;
each said one or more scalable cuboids has a first wall, a second wall, a third wall, a fourth wall, a ceiling, a floor, wherein each may be an interior surface or an exterior surface of said three-dimensional model of the living space or interior space specified on said floor plan;
each said one or more scalable cuboids may be repeatably resized or scaled to any desired size by selecting one said edge or said corner with said cursor, using said mouse or track pad, and moving said edge or said corner to expand or contract said edge or said corner or increase or decrease its size as desired, when said mouse or track pad is then released to leave said edge or said corner at this new location, thereby sizing or re-sizing said scalable cuboid;
each said one or more scalable triangular prisms is a triangular prism shaped member or three-sided prism shaped member that is created in said software and depicted on said screen as an overlay on said floor plan;
each said one or more scalable triangular prisms has a first wall, a second wall, a third wall, a ceiling, a floor, wherein each may be an interior surface or an exterior surface of said three-dimensional model of the living space or interior space specified on said floor plan;
each said one or more scalable cuboids may be repeatably resized or scaled to any desired size by selecting one said edge or said corner with said cursor, using said mouse or track pad, and moving said edge or said corner to expand or contract said edge or said corner or increase or decrease its size as desired, when said mouse or track pad is then released to leave said edge or said corner at this new location, thereby sizing or re-sizing said scalable triangular prism;
each said room on each said floor of said floor plan is filled with said one or more scalable cuboids and/or said one or more scalable triangular prisms so that all said rooms are completely filled with said scalable cuboids and/or said scalable triangular prisms, with exact alignment between these members; wherein, all said interior surfaces of each said scalable cuboid and each said scalable triangular prism are coincident with the contiguous surface of their neighboring said scalable cuboid or said scalable triangular prism, so that there are no gaps or overlap between these members and all said exterior surfaces of each said scalable cuboid and each scalable triangular prism are coincident with the contiguous surface of the corresponding wall, ceiling, or floor as specified on said floor plan so that there are no gaps or overlap between these members;
all said interior surfaces of each said scalable cuboid and each said scalable triangular prism are effectively removed to form a unitary piece or model that is said three dimensional model of the living space or interior space of a house or building;
adding all windows designated in said floor plan to the corresponding said exterior surface of said three-dimensional model of the living space or interior space as specified on said floor plan; and
adding all doors designated in said floor plan to the corresponding said exterior surface of said three-dimensional model of the living space or interior space specified on said floor plan.

2. The process for creating a real-time tabulation or matrix of exterior surface data of a three-dimensional model of the living space or interior space of a house or building, for use in sizing HVAC systems, sizing air ducting systems, or other energy modeling for the house or building, comprising the steps of:
obtaining a computer with: a keyboard, a screen or monitor, and a mouse or track pad used to direct a cursor on said screen or monitor;
loading or installing a software on said computer;
obtaining a digital file of a floor plan drawing of the living space or interior space of a house or building that shows a scaled two-dimensional depiction of all walls, all floors, all doors, and all windows;
uploading or importing said digital file into said software on said computer;
entering the wall height specified on said floor plan into said software on said computer;
entering the ceiling height or plate height specified on said floor plan into said software on said computer;
adding one or more scalable cuboids and/or one or more scalable triangular prisms to fill the entire living space or interior space of a house or building without any gaps or overlap between each of said one or more scalable cuboids and/or said one or more scalable triangular prisms to created said three-dimensional model of the living space or interior space specified on said floor plan; wherein,
each said one or more scalable cuboids is a cuboid or hollow cube shaped member that is created in said software and depicted on said screen as an overlay on said floor plan;
each said one or more scalable cuboids has a first wall, a second wall, a third wall, a fourth wall, a ceiling, a floor, wherein each may be an interior surface or an exterior surface of said three-dimensional model of the living space or interior space specified on said floor plan;
each said one or more scalable cuboids may be repeatably resized or scaled to any desired size by selecting one said edge or said corner with said cursor, using said mouse or track pad, and moving said edge or said corner to expand or contract said edge or said corner or increase or decrease its size as desired, when said mouse or track pad is then released to leave said edge or said corner at this new location, thereby sizing or re-sizing said scalable cuboid;
each said one or more scalable triangular prisms is a triangular prism shaped member or three-sided prism shaped member that is created in said software and depicted on said screen as an overlay on said floor plan;
each said one or more scalable triangular prisms has a first wall, a second wall, a third wall, a ceiling, a floor, wherein each may be an interior surface or an exterior surface of said three-dimensional model of the living space or interior space specified on said floor plan;
each said one or more scalable cuboids may be repeatably resized or scaled to any desired size by selecting one said edge or said corner with said cursor, using said mouse or track pad, and moving said edge or said corner to expand or contract said edge or said corner or increase or decrease its size as desired, when said mouse or track pad is then released to leave said edge or said corner at this new location, thereby sizing or re-sizing said scalable triangular prism;
each said room on each said floor of said floor plan is filled with said one or more scalable cuboids and/or said one or more scalable triangular prisms so that all said rooms are completely filled with said scalable cuboids and/or said scalable triangular prisms, with exact alignment between these members; wherein, all said interior surfaces of each said scalable cuboid and each said scalable triangular prism are coincident with the contiguous surface of their neighboring said scalable cuboid or said scalable triangular prism, so that there are no gaps or overlap between these members and all said exterior surfaces of each said scalable cuboid and each scalable triangular prism are coincident with the contiguous surface of the corresponding wall, ceiling, or floor as specified on said floor plan so that there are no gaps or overlap between these members;
all said interior surfaces of each said scalable cuboid and each said scalable triangular prism are effectively removed to form a unitary piece or model that is said three dimensional model of the living space or interior space of a house or building;
adding all windows designated in said floor plan to the corresponding said exterior surface of said three-dimensional model of the living space or interior space as specified on said floor plan;
adding all doors designated in said floor plan to the corresponding said exterior surface of said three-dimensional model of the living space or interior space specified on said floor plan; and
said real-time tabulation or matrix of exterior surface data of a three-dimensional model of the living space or interior space includes a tabulation of each said exterior surface of said three-dimensional model of the living space with an accurate surface area measurement of each said exterior surface of said three-dimensional model of the living space.
